(19) United States
(12) Patent Application Publication
(10) Pub. No.: US 2022/0149313 A1
(43) Pub. Date: May 12, 2022

(54) DISPLAY DEVICE AND ELECTRONIC DEVICE

(71) Applicant: Semiconductor Energy Laboratory Co., Ltd., Atsugi-shi, Kanagawa-ken (JP)

(72) Inventors: Daiki NAKAMURA, Atsugi (JP); Nozomu SUGISAWA, Isehara (JP); Shuhei YOSHITOMI, Ayase (JP); Kensuke YOSHIZUMI, Atsugi (JP)

(21) Appl. No.: 17/435,811

(22) PCT Filed: Mar. 9, 2020
(86) PCT No.: PCT/IB2020/052003

§ 371 Date: Sep. 2, 2021

(30) Foreign Application Priority Data
Mar. 21, 2019 (JP) 2019-053962

(51) Int. Cl. H01L 51/52; G06F 3/041

(52) U.S. Cl. CPC H01L 51/524; G06F 3/0412; H01L 51/0097; H01L 2251/558; H01L 2251/5338

(57) ABSTRACT

A flexible display is prevented from being damaged. A display device having thickness and flexibility both is provided. The display device includes a display panel with a display element. The display panel includes a first film, a second film, and a bonding layer. The bonding layer is positioned between the first film and the second film, and has a function of attaching the first film and the second film to each other. The display element is supported by the first film. The display panel has a bending modulus of elasticity being higher than or equal to 0.01 times a tensile modules of elasticity and lower than one times the tensile modulus of elasticity.

### TECHNICAL FIELD

One embodiment of the present invention relates to a display device. One embodiment of the present invention relates to a display device with a flexible display, in particular.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device generally means a device that can function by utilizing semiconductor characteristics.

### BACKGROUND ART

Flexible displays whose display surfaces can be curved have been actively developed. Light-emitting elements such as organic EL (electroluminescence) elements, liquid crystal element, and the like are typical display elements used in flexible displays.

The basic configuration of an organic EL element is a configuration in which a layer containing a light-emitting organic compound is provided between a pair of electrodes. By applying a voltage to this element, light emission can be obtained from the light-emitting organic compound. A display device using such an organic EL element does not require a light source such as a backlight; thus, a thin, lightweight, high-contrast, and low-power display device can be achieved.

Patent Document 1 discloses a flexible light-emitting device using an organic EL element, for example.

### REFERENCE

### [Patent Document]

[Patent Document 1] Japanese Published Patent Application No. 2014-197522

### SUMMARY OF THE INVENTION

### Problems to be Solved by the Invention

A problem of flexible displays, which are extremely thinner than conventional displays, is the difficulty in obtaining higher mechanical strength. When a flexible display is made to function as a touch panel, in particular, a strong touch by a finger, a stylus, or the like on a display surface might damage the flexible display. When a protective film or the like is attached to the display surface side of the flexible display to prevent damage, the thickness of the flexible display as a whole increases and the flexibility decreases, which has been a problem.

An object of one embodiment of the present invention is to prevent damage to a flexible display. Another object is to provide a display device having thickness and flexibility both. Another object is to provide a display device or an electronic device having high reliability. Another object is to provide a display device or an electronic device having a novel configuration.

Note that the description of these objects does not preclude the existence of other objects. One embodiment of the present invention does not have to achieve all these objects. Objects other than these can be derived from the description of the specification, the drawings, the claims, and the like.

### Means for Solving the Problems

One embodiment of the invention is a display device including a display panel with a display element. The display panel includes a first film, a second film, and a first bonding layer. The first bonding layer is positioned between the first film and the second film and has a function of attaching the first film and the second film to each other. The display element is supported by the first film. The display panel has a bending modulus of elasticity being higher than or equal to 0.01 times a tensile modulus of elasticity and lower than one times the tensile modulus of elasticity.

Another embodiment of the invention is a display device including a display panel with a display element. The display panel includes a first film, a second film, and a first bonding layer. The first bonding layer is positioned between the first film and the second film and has a function of attaching the first film and the second film to each other. The display element is supported by the first film. The display panel has a bending modulus of elasticity being higher than or equal to 0.01 times a tensile modulus of elasticity and lower than one times the tensile modulus of elasticity. The first bonding layer has viscoelasticity and is higher in stretchability than the first film and the second film.

Another embodiment of the invention is a display device including a display panel with a display element. The display panel includes a first film, a second film, and a first bonding layer. The first bonding layer is positioned between the first film and the second film and has a function of attaching the first film and the second film to each other. The display element is supported by the first film. The display panel has a bending modulus of elasticity being higher than or equal to 0.01 times a tensile modulus of elasticity and lower than one times the tensile modulus of elasticity. The display panel is changed in shape, when a portion of the display panel is bent, such that an end face of the first film and an end face of the second film relatively move away from each other.

In the above configuration, it is preferable that the display panel have a bending modulus of elasticity being higher than or equal to 0.01 times the tensile modulus of elasticity and lower than or equal to 0.2 times the tensile modulus of elasticity.

In the above configuration, it is preferable that the second film have a function of a touch sensor or a circularly polarizing plate.

In the above, it is preferable that the first film include one or more of an epoxy resin, an aramid resin, an acrylic resin, an imide resin, an amide resin, an amide-imide resin, and glass.

In the above, it is preferable that the second film include one or more of a urethane resin, an acrylic resin, a silicone resin, a fluorine resin, an olefin resin, a vinyl resin, a styrene resin, an amide resin, an ester resin, and an epoxy resin.

In the above, it is preferable that the first bonding layer include a rubber-like or gel-like material including silicone, an acrylic resin, or a urethane resin.

In the above, the display device may further include a second bonding layer and a third film. The second bonding layer overlaps with the first bonding layer with the second film therebetween and has a function of attaching the second film and the third film to each other. It is preferable that the second bonding layer have viscoelasticity and be higher in stretchability than the first film and the second film. It is preferable that the third film include one or more of a urethane resin, an acrylic resin, a silicone resin, a fluorine resin, an olefin resin, a vinyl resin, a styrene resin, an amide resin, an ester resin, and an epoxy resin.

One embodiment of the present invention is an electronic device including the display device according to any one of the above, and a protective cover. The protective cover includes a first portion with a flat surface and a second portion with a curved surface adjacent to the first portion, and is provided to cover a display surface of the display panel. The display panel has a portion held by the protective cover along the first portion and the second portion.

One embodiment of the present invention is an electronic device including the display device according to any one of the above, a first support, a second support, and a joint. The first support and the second support are joined to each other with the joint. The display panel includes a first portion supported by the first support, a second portion supported by the second support, and a third portion positioned between the first portion and the second portion. The joint is configured to allow the third portion of the display panel to be bent such that the display surface is convex or concave, thereby enabling the first support and the second support to overlap with each other.

Another embodiment of the present invention is an electronic device including the display device according to any one of the above, a first support, a second support, a third support, a first joint, and a second joint. The first support and the second support are joined to each other with the first joint. The second support and the third support are joined to each other with the second joint. The display panel includes a first portion supported by the first support, a second portion supported by the second support, a third portion supported by the third support, a fourth portion positioned between the first portion and the second portion, and a fifth portion positioned between the second portion and the third portion. The first joint is configured to allow the fourth portion of the display panel to be bent convexly, thereby enabling the first support and the second support to overlap with each other. The second joint is configured to allow the fifth portion of the display panel to be bent concavely, thereby enabling the second support and the third support to overlap with each other.

### Effect of the Invention

According to one embodiment of the present invention, damage to a flexible display can be prevented. Alternatively, a display device having thickness and flexibility both can be provided. Alternatively, a display device or an electronic device having high reliability can be provided. Alternatively, a display device or an electronic device having a novel configuration can be provided.

Note that the description of these effects does not preclude the existence of other effects. One embodiment of the present invention does not have to have all of these effects. Effects other than these can be derived from the description of the specification, the drawings, the claims, and the like.

### BRIEF DESCRIPTION OF THE DRAWINGS

FIG. 1A to FIG. 1C illustrate a configuration example of a display panel.

FIG. 2A to FIG. 2C illustrate a configuration example of a display panel.

FIG. 3A and FIG. 3B illustrate a configuration example of a display panel.

FIG. 4A to FIG. 4E illustrate application examples of a display panel.

FIG. 5A to FIG. 5D illustrate application examples of a display panel.

FIG. 6A and FIG. 6B illustrate an application example of a display panel.

FIG. 7A and FIG. 7B illustrate an application example of a display panel.

FIG. 8A and FIG. 8B illustrate application examples of a display panel.

FIG. 9A to FIG. 9C illustrates a configuration example of a display device.

FIG. 10 illustrates a cross-sectional configuration example of a display device.

FIG. 11 illustrates a cross-sectional configuration example of a display device.

FIG. 12A illustrates a block diagram of a display device. FIG. 12B and FIG. 12C illustrate circuit diagrams.

FIG. 13A, FIG. 13C, and FIG. 13D are each a circuit diagram of a display device. FIG. 13B shows a timing chart.

FIG. 14A to FIG. 14E illustrate configuration examples of a pixel.

FIG. 15A to FIG. 15C illustrate configuration examples of an electronic device.

FIG. 16A to FIG. 16E illustrate configuration examples of electronic devices.

FIG. 17A to FIG. 17G illustrate configuration examples of electronic devices.

FIG. 18A to FIG. 18D illustrate configuration examples of electronic devices.

FIG. 19A and FIG. 19B show the results of measuring a tensile modules of elasticity and a bending modulus of elasticity related to an example.

FIG. 20A1 to FIG. 20C2 show micrographs of samples related to the example.

### MODE FOR CARRYING OUT THE INVENTION

Hereinafter, embodiments will be described with reference to the drawings. Note that the embodiments can be implemented in many different modes, and it will be readily understood by those skilled in the art that modes and details thereof can be changed in various ways without departing from the spirit and scope thereof. Thus, the present invention should not be construed as being limited to the following description of the embodiments.

Note that in configurations of the invention described below, the same portions or portions having similar functions are denoted by the same reference numerals in different drawings, and a description thereof is not repeated. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Thus, they are not limited to the illustrated scale.

Note that in this specification and the like, the ordinal numbers such as “first” and “second” are used in order to avoid confusion among components and do not limit the number.

Note that the expressions indicating directions such as “over” and “under” are basically used to correspond to the directions of drawings. However, in some cases, the direction indicating “over” or “under” in the specification does not correspond to the direction in the drawings for the purpose of description simplicity or the like. For example, when a stacked order (or formation order) of a stacked body or the like is described, even in the case where a surface on which the stacked body is provided (e.g., a formation surface, a support surface, an attachment surface, or a planarization surface) is positioned above the stacked body in the drawings, the direction and the opposite direction are referred to as “under” and “over”, respectively, in some cases.

In this specification and the like, a display panel that is one embodiment of a display device has a function of displaying (outputting) an image or the like on (to) a display surface. Therefore, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

Note that in this specification and the like, a touch panel that is one embodiment of a display device has a function of displaying an image or the like on a display surface and a function of a touch sensor capable of sensing the contact, press, approach, or the like of a sensing target such as a finger or a stylus with or to the display surface. Thus, the touch panel is one embodiment of an input/output device.

A touch panel can also be referred to as, for example, a display panel (or a display device) with a touch sensor, or a display panel (or a display device) having a touch sensor function. A touch panel can include a display panel and a touch sensor panel. Alternatively, a touch panel can have a function of a touch sensor in the display panel or on the surface of the display panel.

In this specification and the like, a substrate of a touch panel on which a connector and an IC are mounted is referred to as a touch panel module, a display module, or simply a touch panel or the like in some cases.

### Embodiment 1

In this embodiment, a display device of one embodiment of the present invention will be described.

The display device of one embodiment of the present invention includes a display panel with a display element. The display panel includes a first film, a second film, and a bonding layer positioned therebetween. The bonding layer has a function of bonding the first film to the second film.

The display element is provided to be supported by the first film. Thus, the first film can be regarded as a substrate that supports the display element, or a support.

The second film has a function of a protective film for protecting the display element. A portion of the second film can function as a display surface of the display panel. The second film may also have a function of a sensor such as a touch sensor. The second film may also have a function of an optical component such as a circularly polarizing plate.

A feature of the display panel of one embodiment of the present invention is that the bending modulus of elasticity is lower than the tensile modulus of elasticity. Specifically, the bending modulus of elasticity is higher than or equal to 0.01 times the tensile modulus of elasticity and lower than one times the tensile modulus of elasticity, preferably higher than or equal to 0.01 times the tensile modulus of elasticity and lower than or equal to 0.5 times the tensile modulus of elasticity, more preferably higher than or equal to 0.01 times the tensile modulus of elasticity and lower than or equal to 0.2 times the tensile modulus of elasticity, still more preferably higher than or equal to 0.01 times the tensile modulus of elasticity and lower than or equal to 0.1 times the tensile modulus of elasticity. The lower the bending modulus of elasticity of the display panel as compared with the tensile modulus of elasticity, the more preferable; the bending modulus of elasticity may be lower than 0.01 times the tensile modulus of elasticity.

In this specification and the like, a bending modulus of elasticity refers to Young's modulus calculated from a stress-strain curve (S-S curve) measured by a bending test. A tensile modulus of elasticity refers to Young's modulus calculated from a stress-strain curve (S-S curve) measured by a tensile test.

The bending test can be carried out in accordance with or with reference to standards such as ISO178, JIS K7171, and ASTM D790. The tensile test can be carried out in accordance with or with reference to standards such as ISO527, JIS K7161, and JIS K7127.

Here, when a single flexible film is considered, the bending modulus of elasticity and the tensile modulus of elasticity are the same values in principle. Next, in the case where a plurality of flexible films are bonded with an adhesive or the like to make up a stacked film, the bending modulus of elasticity tends to be higher than the tensile modulus of elasticity. In other words, the stacked film tends to be less easily bent than a single flexible film, even when the stacked film and the single flexible film have the same thickness.

However, the bending modulus of elasticity is lower than the tensile modulus of elasticity in the display panel of one embodiment of the present invention; thus, the display panel can be bent with small force. In addition, increasing the tensile modulus of elasticity can make the display panel less likely to expand and contract in a stretching direction. In this way, this display panel is less likely to expand and contract even in the case where the display panel is repeatedly bent and stretched; thus, the display element and a wiring included in the display panel can be prevented from being damaged, which results in the improvement in durability of the display panel.

A display panel having the above characteristics can be obtained when a plurality of neutral planes are provided in the display panel. More specifically, the display panel has a stacked configuration where the neutral plane of the first film is positioned in the first film and the neutral plane of the second film is positioned in the second film, when the display panel is bent.

As a more preferred mode, the use of a material with viscoelasticity (a viscoelastic body), which is a property having viscosity and elasticity both, as the bonding layer that bonds the first film to the second film can be given. The viscoelastic body has a property of being distorted when external force is applied, and a property of holding the distortion constant and losing stress (to be 0) when the applied external force is maintained constant. It is particularly preferable to use a material whose viscosity is greater than elasticity and that can be deformed with small force. For example, a viscoelastic body with a modulus of elasticity of 1 kPa to 1 MPa inclusive, preferably 5 kPa to 500 kPa inclusive, more preferably 10 kPa to 200 kPa inclusive can be used as the bonding layer.

The stretchability of the bonding layer is preferably higher than those of the first film and the second film. More specifically, it is preferable that the bonding layer be most easily stretched when the first film, the second film, and the bonding layer are pulled with the same force.

With the use of such a material for the bonding layer, when external force that bends the display panel is applied, the bonding layer is distorted such that stress is relieved in a state where the bonding layer bonds the first film to the second film. Thus, the first film and the second film can be bent without stretching, at different neutral planes. As a result, the display panel can be bent with extremely small force.

Furthermore, when the display panel is held in a bent state, the distortion of the bonding layer becomes constant as mentioned above, so that restoring force is not generated; thus, the shape can be maintained as it is even without great force being applied. In the case where the restoring force of the first film and the second film is negligibly small, in particular, the shape of the display panel is maintained.

In addition, the display panel of one embodiment of the present invention has the following feature: when external force is applied to the display panel in a flat state to bend the display panel to have a predetermined curvature, and then the external force is eliminated after the bent state is maintained for a certain period of time, the display panel deforms slowly (taking several seconds to several tens of seconds), because of the restoring force of the first film and the second film, such that the curvature becomes smaller, and returns to the original flat state. In some cases, the display panel does not completely return to the original flat state.

With the use of a material with viscoelasticity for the bonding layer, the bonding layer deforms when external force is applied from the display surface side to the display panel, whereby the stress can be suitably relieved. In other words, the bonding layer functions as an impact-relaxing layer; thus, the display element, a pixel circuit, or the like provided in the first film can be prevented from being damaged.

By contrast, in the case where the above-described adhesive is used, the stack becomes less likely to be bent as the adhesive becomes thicker; however, in one embodiment of the present invention, the bending modulus of elasticity can be smaller as the thickness of the bonding layer becomes thicker. Since the bonding layer is provided to cover the display element of the display panel, thickening the bonding layer can improve the function of protecting the display element, whereby a display device with higher reliability can be obtained.

Examples that are more specific will be described below with reference to drawings.

### Configuration Example

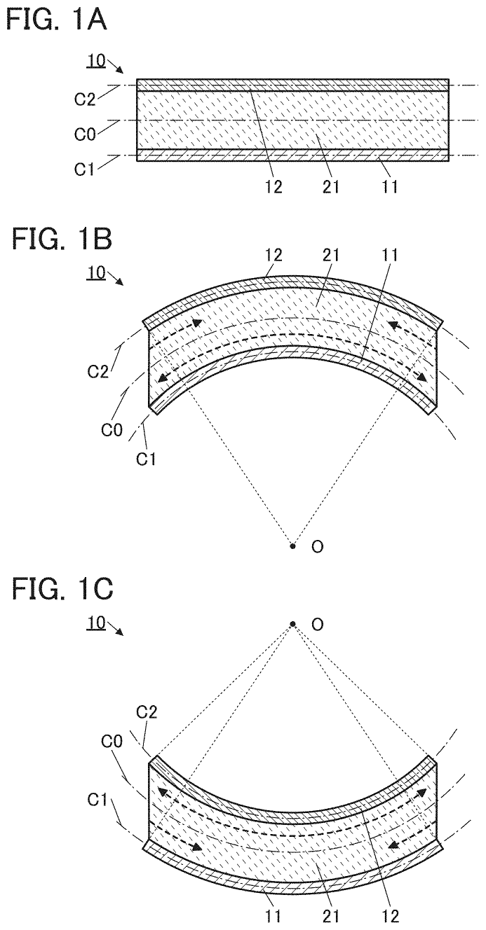

FIG. 1A is a cross-sectional schematic view of a display panel 10 of one embodiment of the present invention. The display panel 10 includes a film 11, a film 12, and a bonding layer 21 between these films.

The film 11, at least a portion of which has flexibility, can be bent. The film 11 includes a plurality of pixels arranged in a matrix and can display an image.

At least one or more display elements are provided in the pixels provided in the film 11. The pixel may include a transistor, a wiring, or the like.

As organic EL element can typically be used as the display element. Other than that, a variety of display elements such as light-emitting elements such as an inorganic EL element and an LED element, a liquid crystal element, a microcapsule, an electrophoretic element, an electrowetting element, an electrofluidic element, an electrochromic element, and a MEMS element can be used.

The film 11 is not limited to what is composed of a single film, and may be a stack of a plurality of thin sheet-like components. The film 11 may be a stacked body in which a display element, a transistor, a wiring, an electrode, and the like that make up the pixel, a driver circuit, or the like are sealed between a pair of films, for example. Although the configuration including the film 11, the film 12, and the bonding layer 21 is denoted as the display panel 10 here, the film 11 may have a function of displaying an image by itself.

As specific examples of a sheet-like component included in the film 11, a resin such as an epoxy resin, an aramid resin, an acrylic resin, an imide resin, or an amide-imide resin, or glass that is thin enough to have flexibility can be used. Alternatively, an ester resin such as polyethylene terephthalate (PET) or polyethylene naphthalate (PEN), an acrylonitrile resin, a methyl methacrylate resin, polycarbonate (PC), polyether sulfone (PES), an amide resin (e.g., nylon or aramid), a siloxane resin, a cycloolefin resin, a styrene resin, a urethane resin, a vinyl chloride resin, a polyvinylidene chloride resin, a propylene resin, polytetrafluoroethylene (PTFE), an ABS resin, cellulose nanofiber, or the like can be used.

The film 12, at least a portion of which has flexibility, can be bent. The film 12 is positioned on the display surface side of the display panel 10, and has a function of protecting the display element or the like provided in the film 11. The film 12 has a light-transmitting property; a user can see an image displayed on the film 11 through the film 12 and the bonding layer 21. The surface of the film 12, which is on the other side than the film 11, functions as a display surface of the display panel 10.

The film 12 may also have a function of a touch sensor panel or a function of an optical film. As a touch sensor panel, the film 12 can include a sensor element such as a capacitive touch sensor, an optical sensor, or a pressure-sensitive touch sensor. As an optical film, a circularly polarizing plate, an anti-reflection film (including an AR (Anti-Reflection) film and an AG (Anti-Glare) film), and the like can be given, for example.

For the film 12, a sheet-like component including at least one or more of a urethane resin, an acrylic resin, a silicone resin, a fluorine resin, an olefin resin, a vinyl resin, a styrene resin, an amide resin, an ester resin, and an epoxy resin is preferably used. In particular, a urethane resin has a relatively high dielectric constant and can increase the sensitivity when a capacitive touch sensor is used. In addition, a urethane resin is preferred because it can give excellent slidability and a self-healing function to the surface of the film 12.

An organic resin having a self-healing function is preferably used as the material that is positioned in the outermost surface of the film 12, in particular, in which case surface scattering caused by a scratch or the like can be prevented and display quality can be maintained. When a water-repellent or oil-repellent resin is used as the organic resin or surface treatment is performed to make the outermost surface of the film 12 water repellent or oil repellent, the surface of the film 12 can be prevented from being contaminated with fingerprint marks or the like. In other words, the film 12 can have a stain-resistant property. As a material having a self-healing function, in addition to a urethane resin mentioned above, materials including polyrotaxane, cyclodextrin, polyphenylene ether, or the like can be used. More preferably, in that case, the film 12 has a configuration in which the organic resin having a self-healing function is stacked over a sheet-like component composed of one or more of a urethane resin, an acrylic resin, and a silicone resin described above.

The slidability of the film 12 is preferably improved by coating, surface treatment, putting a film having excellent slidability, or the like.

The bonding layer 21 is positioned between the film 11 and the film 12, and has a function of bonding these films. A material that transmits visible light and has viscoelasticity is preferably used for the bonding layer 21. The use of a material whose viscosity is higher than its elasticity is particularly preferable for the bonding layer 21.

The bonding layer 21 has a property of changing its shape, when external force is applied, and maintaining the shape because of stress relaxation. The relaxation time taken for stress relaxation of the bonding layer 21 is preferably 0.01 seconds to 10 seconds inclusive, preferably 0.05 seconds to 5 seconds inclusive. A material whose relaxation time is shorter than 0.01 seconds is close to a fluid, and is decreased in function of attaching the film 11 and the film 12 to each other. Meanwhile, a material whose relaxation time is longer than 10 seconds is close to an elastic body, and makes the bonding layer 21 itself less likely to be bent. Furthermore, the neutral planes of the film 11 and the film 12 move to the bonding layer 21 side at the time when the display panel 10 is bent, as described later, so that greater stress is applied to the film 11 and the film 12.

A viscoelastic body with a relatively low viscosity is preferably used for the bonding layer 21. A viscoelastic body with a low elasticity can also be used. Specifically, for example, a rubber-like material or gel-like material including silicone, an acrylic resin, a urethane resin, or the like is preferably used. In particular, a material such as a silicone gel, a silicon gel including low molecular siloxane, an acrylic gel, or a urethane gel is preferably used.

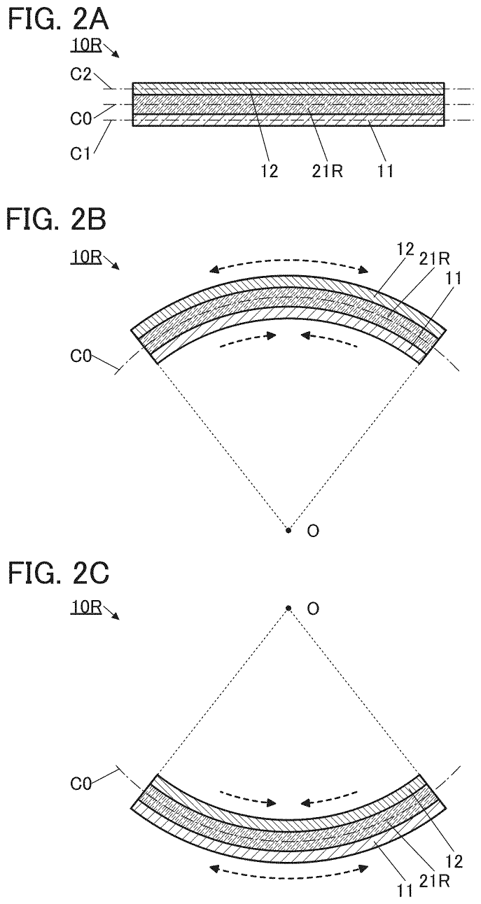

Here, for comparison, a display panel 10R in which the film 11 and the film 12 are attached to each other with an adhesive 21R having high stiffness is described with reference to FIG. 2A. In FIG. 2A, a neutral plane C1 of the film 11, a neutral plane C2 of the film 12, and a neutral plane C0 of the display panel 10R as a whole are each indicated by a dashed-dotted line. The neutral plane C0 is positioned inside the adhesive 21R. The display panel 10R has a configuration in which the film 11 and the film 12 are bonded to each other with the adhesive 21R having high stiffness, and the bending modulus of elasticity is higher than the tensile modulus of elasticity.

FIG. 2B is a schematic cross-sectional view of the display panel 10R being bent such that the display surface is convex. The neutral plane C0 of the display panel 10R is positioned inside the adhesive 21R; thus, for the display panel 10R to be bent, the film 11 needs to contract and the film 12 needs to stretch, as indicated by the dashed arrows in FIG. 2B. FIG. 2C illustrates the display panel 10R being bent such that the display surface is concave. In this case, the film 11 needs to stretch and the film 12 needs to contract.

For preventing the film 11 and the film 12 from being damaged in the display panel 10R shown in FIG. 2A, the adhesive 21R needs to be formed as thin as possible to make the distance between the film 11 and the neutral plane C0 and the distance between the film 12 and the neutral plane C0 as short as possible. Thus, it is difficult to increase the thickness of the adhesive 21R and to increase the mechanical strength of the display panel 10R itself.

FIG. 1A shows the neutral plane C1 of the film 11, the neutral plane C2 of the film 12, and a neutral plane C0 of the display panel 10, in the display panel 10. The neutral plane C1 is positioned inside the film 11, the neutral plane C2 is positioned inside the film 12, and the neutral plane C0 is positioned inside the bonding layer 21.

FIG. 1B illustrates the display panel 10 being bent such that the display surface is convex.

When the display panel 10 is bent, the bonding layer 21 changes its shape such that a portion closer to the film 11 stretches and a portion closer to the film 12 contracts, with the vicinity of the neutral plane C0 serving as a boundary, as indicated by dashed arrows in FIG. 1B. As a result, the film 11 can be bent without contracting, and the film 12 can be bent without stretching.

In the above manner, the display panel 10 can be bent with small force as the bonding layer 21 changes its shape; thus, the thickness of the bonding layer 21 can be increased. Increasing the thickness of the bonding layer 21 can enhance the impact resistance of the display panel 10 and improve its reliability. The thickness of the bonding layer 21 can be, for example, 1 μm to 10 mm inclusive, preferably 5 μm to 5 mm inclusive, more preferably 10 μm to 3 mm inclusive, and still more preferably 20 μm to 2 mm inclusive.

FIG. 1C illustrates the display panel 10 being bent such that the display surface is concave. At this time, the bonding layer 21 changes its shape such that the portion closer to the film 11 contracts and the portion closer to the film 12 stretches, with the vicinity of the neutral plane C0 serving as a boundary.

As to the shape of the display panel 10 in FIG. 1B, the end face of the film 11 is positioned outside of the line connecting the end face of the film 12 on the outer side and a flexural center O. In other words, when seen from a direction perpendicular to the surface of the film 12 near the end face of the film 12, the end portion of the film 11 protrudes outside from the end portion of the film 12. When the display panel 10 is gradually bent from a flat state in this manner, the display panel 10 changes its shape while the end face of the film 11 and the end face of the film 12 move relatively in such a way that they are more apart from each other. This is because the display panel 10 is bent without the film 11 and the film 12 stretching or contracting.

By contrast, the display panel 10R shown in FIG. 2B has a shape in which the film 11 on the inner side contracts and the film 12 on the outer side stretches since the adhesive 21R has stiffness; the end portions of these films do not move away from each other when the display panel 10R is bent.

Although an example including a pair of films and one bonding layer 21 is described as the display panel 10 here, the display panel 10 may have a configuration in which three or more films are stacked with the bonding layer 21 therebetween, without being limited to this example.

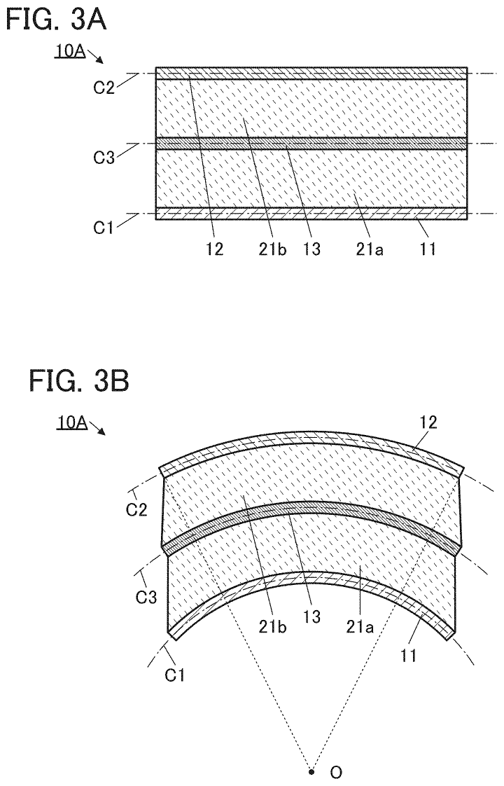

FIG. 3A illustrates an example of a display panel 10A including a film 13 between the film 11 and the film 12. A bonding layer 21a is provided between the film 11 and the film 13, and a bonding layer 21b is provided between the film 13 and the film 12. In FIG. 3A, a neutral plane C3 of the film 13 is indicated by a dashed-dotted line.

A material similar to that of the bonding layer 21 can be used for the bonding layer 21a and the bonding layer 21b. For the film 13, a material with a light-transmitting property, which is similar to the film 12, can be used. A film having at least one of a function of a touch sensor panel and a function of an optical film can be used for the film 13, and a film having at least one of high slippiness and a self-healing property can be used for the film 12, for example.

FIG. 3B illustrates the panel 10A being bent such that the display surface is convex. Similarly to the display panel 10, the display panel 10A can be bent without any of the film 11, the film 12, and the film 13 stretching or contracting, as the bonding layer 21a and the bonding layer 21b change in shapes. The display panel 10A in FIG. 3B has a shape in which the end face of the film 13 is positioned outside of the line connecting the end face of the film 12 on the outer side and a flexural center O, and the end face of the film 11 is positioned further outside. In other words, when seen from a direction perpendicular to the surface of the film 12 near the end face of the film 12, the end face of the film 13 is more outside than the end face of the film 12, and the end face of the film 11 is more outside than the end face of the film 13 in a similar manner. In this way, when the outermost film is regarded as a benchmark, a film closer to the flexural center O has more deviation of the end face.

### Application Example

The display panel of one embodiment of the present invention can be used in a display unit of an electronic device. In that case, the display panel can be incorporated in the electronic device in a form where the display surface is flat without being bent, or in a form where a portion of the display panel is bent and fixed. Specifically, the display panel of one embodiment of the present invention can be incorporated in a foldable device such as an electronic device that can be folded in two such that a display surface faces inside or outside or an electronic device with a display panel capable of being folded in three or more.

### Application Example 1

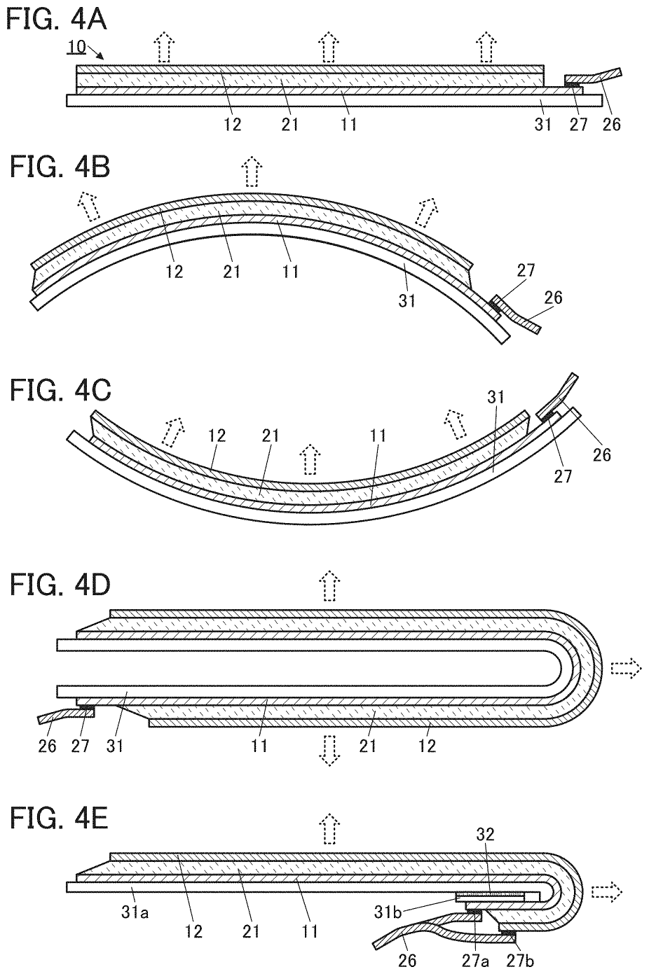

FIG. 4A shows an example of a case where the display panel 10 without being bent is used. FIG. 4A shows the display panel 10, a support 31, an FPC 26, and a connector 27. In FIG. 4A, the direction in which light is emitted when the display panel 10 displays an image is schematically indicated by dashed arrows.

The support 31 is a component that supports the display panel 10. The support 31 is positioned on the opposite side from the display surface side of the display panel 10, and supports the film 11. The support 31 may be a portion of a housing of the electronic device, or a component provided inside the housing of the electronic device.

The FPC 26 is electrically connected to an external circuit, and has a function of transmitting a power supply potential or a variety of signals from the circuit to the display panel 10. The FPC 26 is electrically connected via the connector 27 to a terminal or the like included in the film 11. An anisotropic conductive film or the like, for example, can be used for the connector 27.

In the display panel 10 of one embodiment of the present invention, the top surface of the film 11 is protected by the bonding layer 21 having viscoelasticity. Thus, the display panel 10 is superior in mechanical strength such as impact resistance, and can be suitably used for an application in which the display panel 10 is not bent, as shown in FIG. 4A.

### Application Example 2

FIG. 4B and FIG. 4C each show an example of a case where the support 31 with a curved surface is used. FIG. 4B is an example in which the display panel 10 is supported on the convex side of the support 31. FIG. 4C is an example in which the display panel 10 is supported on the concave side of the support 31.

In FIG. 4B, the display panel 10 is bent such that the display surface is convex. As to the vicinity of the end portion of the film 12, the bonding layer 21 is deformed such that the end face thereof stretches, and the end face of the film 11 protrudes outside from the end face of the film 12, when seen from the display surface side.

In FIG. 4C, the display panel 10 is bent such that the display surface is concave. As to the vicinity of the end portion of the film 12, the bonding layer 21 is deformed such that the end face thereof stretches, and the end face of the film 12 protrudes outside from the end face of the film 11, when seen from the display surface side.

In this manner, in the case where the display panel 10 being bent is fixed to the support 31, the restoring force of the display panel 10 for returning to a flat state is extremely small; thus, a defect such as peeling of the display panel 10 from the support 31 can be prevented.

### Application Example 3

FIG. 4D and FIG. 4E each show an example of a case where the display panel 10 has a portion being bent at a 180-degree angle and a flat portion.

In the example shown in FIG. 4D, images can be displayed in opposite directions with the support 31 therebetween. In addition, in the side portion where the support 31 has a curved surface, an image can be displayed along the curved surface.

In the example shown in FIG. 4E, the display panel 10 is supported by two supports, a support 31a and a support 31b. The support 31a mainly supports the display unit of the display panel 10, and the support 31b mainly supports a connecting portion between the display panel 10 and the FPC 26. In this manner, when the display panel 10 is folded such that the connecting portion connecting to the FPC 26 is positioned on the opposite side from the display surface side, a space that is required for incorporating the display panel 10 in an electronic device can be small.

In FIG. 4E, the FPC 26 has a bifurcated shape where one part is electrically connected to the film 11 via a connector 27a and the other part is electrically connected to the film 12 via a connector 27b. Such a configuration can be used in a case where the film 12 functions as a touch sensor panel or the like, for example.

The support 31b may be a protective component for preventing the display panel 10 from being damaged when the FPC 26 is pressure-bonded to the display panel 10, for example. Furthermore, when the support 31b is fixed to the support 31a with a bonding layer 32 as shown in FIG. 4E, physical stress can be prevented from being applied to the display panel 10 during the process of incorporating the FPC 26 in the electronic device.

### Application Example 4

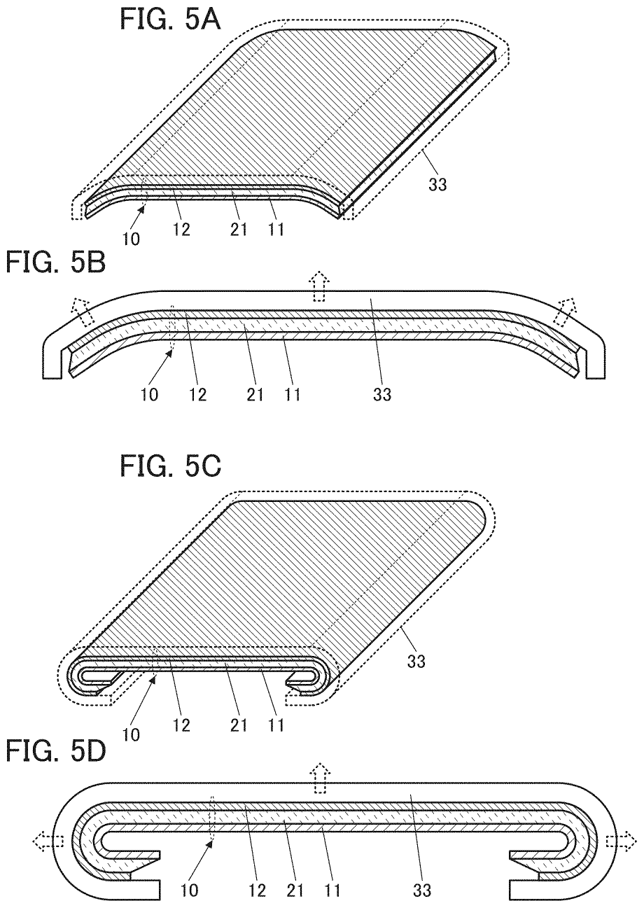

FIG. 5A to FIG. 5D show examples in which the display surface side of the display panel 10 is supported by a support 33. FIG. 5A and FIG. 5C are each a perspective view and FIG. 5B and FIG. 5D are each a cross-sectional view. An FPC and the like are not illustrated in FIG. 5A to FIG. 5D. The support 33 is drawn by a dashed line in FIG. 5A and FIG. 5C.

In the configurations shown in FIG. 5A to FIG. 5D, a material that transmits at least visible light can be used for the support 33. The support 33 can also be referred to as a protective cover. Using plastic or glass (preferably tempered glass), for example, as the support 33 is preferable because the display panel 10 can be suitably protected.

In the example shown in FIG. 5A and FIG. 5B, the surface of the support 33 on the display panel 10 side has a flat portion and a curved portion that is adjacent to the flat portion. The display panel 10 is provided along the surface. In other words, the display panel 10 has a pair of bent portions and a flat portion sandwiched therebetween. The pair of bent portions are each bent such that the display surface is convex.

In the example shown in FIG. 5C and FIG. 5D, a bent portion of the display panel 10 is folded at a 180-degree angle. Thus, images can be displayed not only on the front but also on the sides.

### Application Example 5

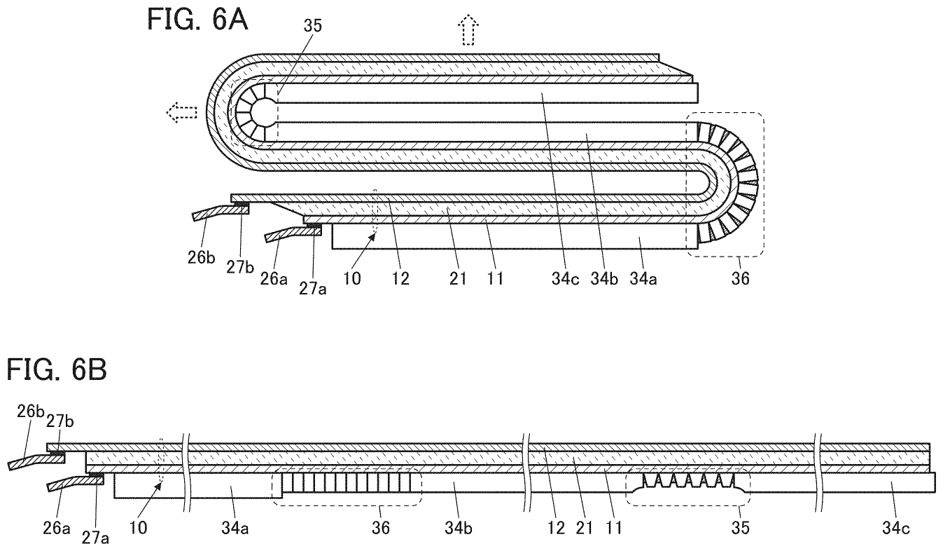

FIG. 6A and FIG. 6B show a configuration in which the display panel 10 can be folded in three. FIG. 6A shows the display panel 10 being folded in three, and FIG. 6B shows the display panel 10 being flat.

The configuration shown in FIG. 6A and FIG. 6B includes the display panel 10, a support 34a, a support 34b, a support 34c, a joint 35, a joint 36, and the like.

The display panel 10 includes a portion supported by the support 34a, a portion supported by the support 34b, and a portion supported by the support 34c. Each of the portions is supported such that the display surface is flat.

The joint 35 joins the support 34b to the support 34c. The joint 35 has a mechanism for joining the support 34b to the support 34c in a way that allows the display panel 10 to be changed in shape reversibly between a state with a flat display surface and a bent state where the display surface faces outside.

The joint 36 joins the support 34a to the support 34b. The joint 36 has a mechanism for joining the support 34a to the support 34b in a way that allows the display panel 10 to be changed in shape reversibly between a state with a flat display surface and a bent state where the display surface faces inside.

With the joint 35 and the joint 36 described above, the display panel 10 can be changed in shape reversibly between the state where the display panel 10 is folded in three as shown in FIG. 6A and the state where the display panel 10 is roughly flat.

FIG. 6A and FIG. 6B show an example in which the joint 35 and the joint 36 each have a configuration with a plurality of pillars being joined. The display panel 10 is supported by one surface of the pillars. It is preferred that two adjacent pillars be provided in contact with each other without a space therebetween on the surface that supports the display panel 10. The pillars in the joint 35 each have a roughly trapezoidal shape in cross section. By contrast, the pillars in the joint 36 each have a roughly rectangular cross-sectional shape.

The joint 35 and the joint 36 may operate in synchronization, or they may operate independently of each other. The configurations of the joint 35 and the joint 36 are not limited to the configurations shown in FIG. 6A and FIG. 6B, and may have various modes. It is preferred in particular that the joint 35 and the joint 36 have a mechanism that enables the display panel 10 to be bent without stretching or contracting.

In addition, FIG. 6A and FIG. 6B show the connector 27a and an FPC 26a that are electrically connected to the film 11, and the connector 27b and an FPC 26b that are electrically connected to the film 12.

### Application Example 6

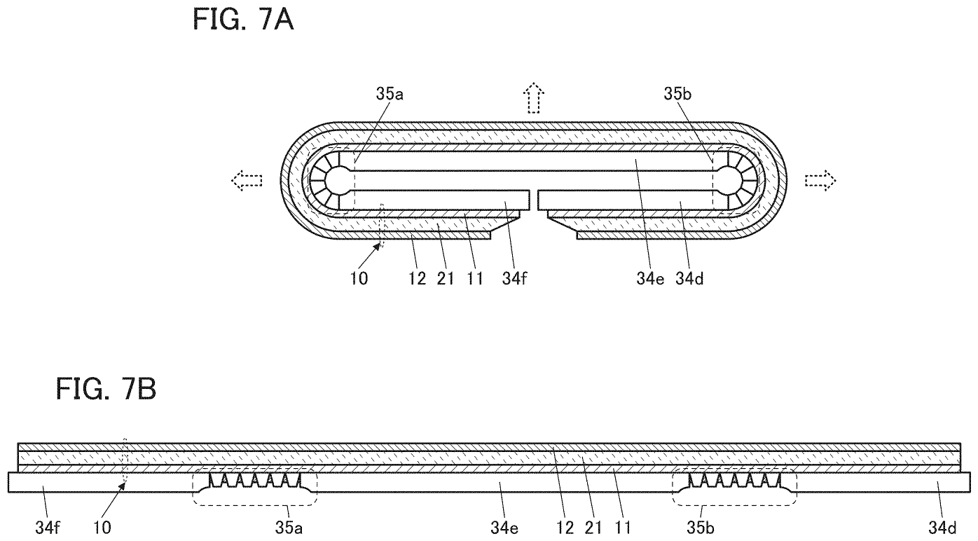

FIG. 7A and FIG. 7B show an example in which two mechanisms that enable the display panel 10 to be bent such that the display surface faces outside are provided. The configuration shown in FIG. 7A and FIG. 7B includes the display panel 10, a support 34d, a support 34e, a support 34f, a joint 35a, a joint 35b, and the like.

The joint 35a joins the support 34f to the support 34e. The joint 35b joins the support 34e to the support 34d. The joint 35 described in the above application example 5 can be referred to for the configurations of the joint 35a and the joint 35b.

### Application Example 7

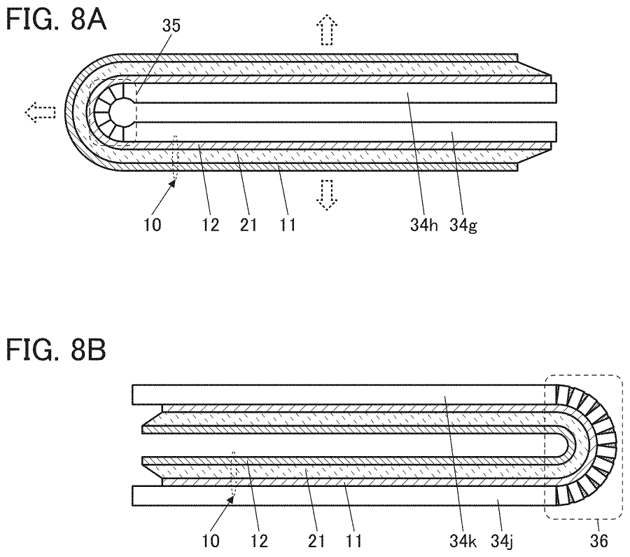

FIG. 8A and FIG. 8B show examples of a configuration in which the display panel 10 can be folded in two.

FIG. 8A is an example in which the display panel 10 is folded in two such that the display surface faces outside. The configuration shown in FIG. 8A includes the display panel 10, a support 34g, a support 34h, the joint 35, and the like. The joint 35 joins the support 34g to the support 34h.

FIG. 8B is an example in which the display panel 10 is folded in two such that the display surface faces inside. The configuration shown in FIG. 8B includes the display panel 10, a support 34j, a support 34k, the joint 36, and the like. The joint 36 joins the support 34j to the support 34k.

The configurations described in the application examples 5 to 7 are superior in portability and carryability when the display panel 10 is folded and superior in browsability when the display panel 10 is opened. The display panel of one embodiment of the present invention has high reliability with respect to repetitive deformation, and thus can be suitably used for a device that can be folded in the above-described manner (also referred to as a foldable device).

The above is the description of the application examples.

At least part of this embodiment can be implemented in combination with the other embodiments described in this specification as appropriate.

### Embodiment 2

In this embodiment, a configuration example of a display panel that can be used in the display device of one embodiment of the present invention will be described.

### Configuration Example

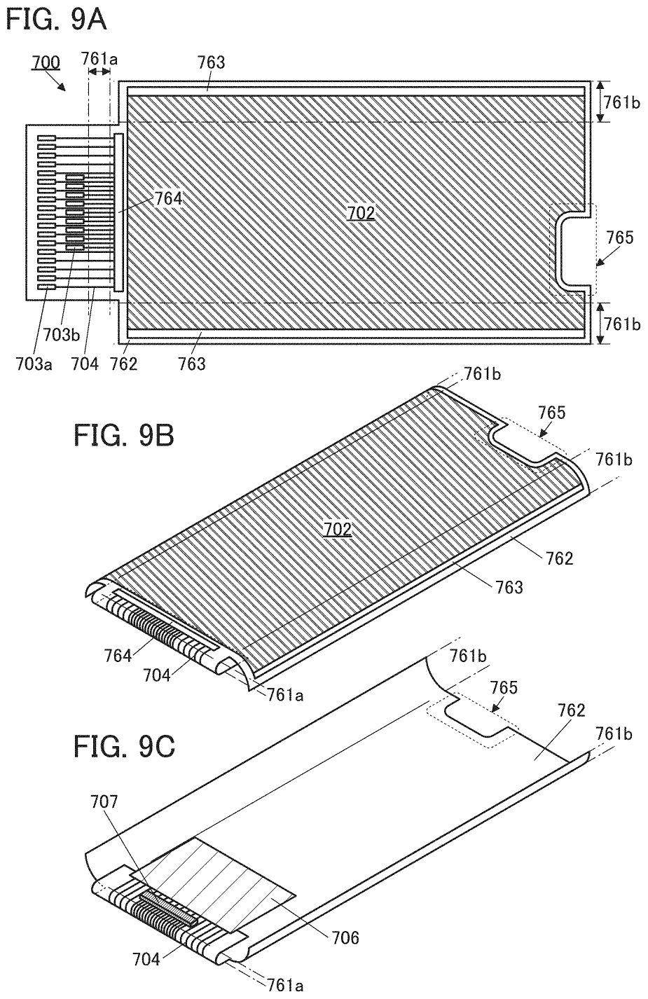

FIG. 9A is a schematic top view of a display device 700. The display device 700 includes a substrate 762 having flexibility. The substrate 762 is provided with a display unit 702, a pair of circuit units 763, a circuit unit 764, a wiring 704, a connection terminal 703a, and a connection terminal 703b.

The circuit unit 763 and the circuit unit 764 have a function of driving the display unit 702. Two circuit units 763 are provided with the display unit 702 positioned therebetween. The circuit unit 764 is provided between the display unit 702 and the wiring 704. The circuit unit 763 has a function of a gate driver, for example, and the circuit unit 764 has a function of a source driver or part of the source driver, for example. The circuit unit 764 may include a buffer circuit or a demultiplexer circuit, for example.

Light-emitting elements or the like can be used as the display elements in the display unit 702. Examples of light-emitting elements are self-luminous light-emitting elements such as an LED (Light Emitting Diode), an OLED (Organic LED), a QLED (Quantum-dot LED), and a semiconductor laser. As the display element, a liquid crystal element such as a transmissive liquid crystal element, a reflective liquid crystal element, or a transflective liquid crystal element can also be used. It is also possible to use a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like, for example. In particular, an organic EL element is preferably used as the display element.

The substrate 762 has a top-view shape where a portion provided with the connection terminal 703a and the connection terminal 703b protrudes from the other portion (the portion provided with the display unit 702). In other words, the width of the portion (also referred to as a protruding portion) of the substrate 762 is smaller than the width of the portion of the substrate 762 where the display unit 702 is provided.

Furthermore, the protruding portion of the substrate 762 includes a region that can be bent (a bent portion 761a) in a region overlapping with the wiring 704. Moreover, the substrate 762 includes a pair of regions that can be bent (bent portions 761b) in a region over which the display unit 702 is provided. As illustrated in FIG. 9A, owing to the protruding shape of the portion of the substrate 762, the bending direction of the bent portion 761a can intersect with the bending direction of the bent portions 761b.

The connection terminal 703a functions as a terminal to which an FPC (Flexible Printed Circuit) is connected, and the connection terminal 703b functions as a terminal to which an IC is connected.

FIG. 9B and FIG. 9C are perspective views of the display device 700 in the case where the substrate 762 is bent at the bent portion 761a and the bent portions 761b to a side opposite to the display surface side. FIG. 9B is a perspective view including the display surface side, and FIG. 9C is a perspective view including the side opposite to the display surface side. In FIG. 9C, an FPC 706 connected to the connection terminal 703a and an IC 707 connected to the connection terminal 703b are shown.

When both sides of the display unit 702 are bent as illustrated in FIG. 9B, at the time of incorporating the display device 700 in an electronic device, bent display portions can be provided on both sides of the electronic device. Thus, a highly functional electronic device can be provided.

Furthermore, as illustrated in FIG. 9B and FIG. 9C, owing to the bent portion 761a, part of the substrate 762 can be folded back to the side opposite to the display surface side. Specifically, the protruding portion of the substrate 762 can be folded back such that the wiring 704 is on an outer side. Accordingly, the connection terminal 703a and the connection terminal 703b can be placed on the side opposite to the display surface side; in addition, the FPC 706 can be placed on the side opposite to the display surface side. Thus, the area of a non-display portion can be reduced when the display device 700 is incorporated in an electronic device.

Furthermore, a notch 765 is provided in the substrate 762. The notch 765 is a portion in which, for example, a lens of a camera included in an electronic device, a variety of sensors such as an optical sensor, a lighting device, a design, or the like can be placed. Owing to the notch of part of the display unit 702, a further highly designed electronic device can be provided. In addition, owing to the notch, the screen occupation ratio with respect to the surface of a housing can be increased.

### Cross-Sectional Configuration Example

Examples of a cross-sectional configuration of the display device will be described below.

### Configuration Example 1

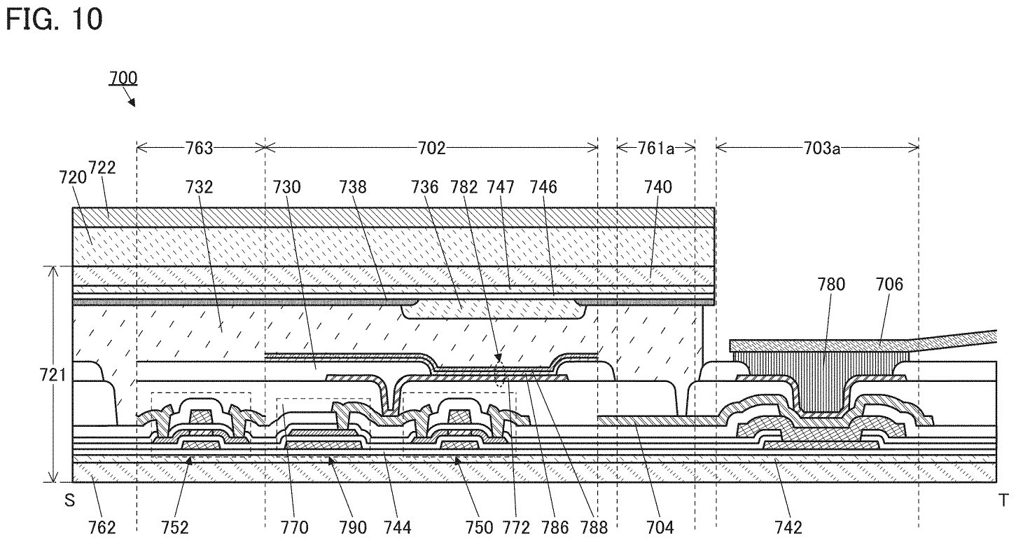

FIG. 10 shows a schematic cross-sectional view of the display device 700. FIG. 10 shows a cross section of the display device 700 including the display unit 702, the circuit unit 763, the bent portion 761a, and the connection terminal 703a that are shown in FIG. 9A. A transistor 750 and a capacitor 790 are provided in the display unit 702. A transistor 752 is provided in the circuit unit 763.

The transistor 750 and the transistor 752 are each a transistor using an oxide semiconductor for a semiconductor layer in which a channel is formed. Note that the transistors are not limited thereto, and a transistor using silicon (amorphous silicon, polycrystalline silicon, or single-crystal silicon) or a transistor using an organic semiconductor for the semiconductor layer can be used.

The transistor used in this embodiment includes a highly purified oxide semiconductor film in which formation of oxygen vacancies is inhibited. The off-state current of the transistors can be reduced significantly. Accordingly, in the pixel employing such a transistor, the retention time of an electrical signal such as an image signal can be extended, and the interval between writes of an image signal or the like can also be set longer. Thus, the frequency of refresh operations can be reduced, so that power consumption can be reduced.

The transistor used in this embodiment can have relatively high field-effect mobility and thus is capable of high-speed operation. With the use of such a transistor capable of high-speed operation for a display device, for example, a switching transistor in a pixel and a driver transistor used in a circuit unit can be formed over one substrate. That is, a structure in which a driver circuit formed using a silicon wafer or the like is not used is possible, in which case the number of components of the display device can be reduced. Moreover, the use of the transistor capable of high-speed operation also in the pixel can provide a high-quality image.

The capacitor 790 includes a lower electrode formed by processing the same film as a film used for the first gate electrode of the transistor 750 and an upper electrode formed by processing the same metal oxide film as a film used for the semiconductor layer. The upper electrode has reduced resistance like a source region and a drain region of the transistor 750. Part of an insulating film functioning as a first gate insulating layer of the transistor 750 is provided between the lower electrode and the upper electrode. That is, the capacitor 790 has a stacked-layer structure in which an insulating film functioning as a dielectric film is positioned between a pair of electrodes. A wiring obtained by processing the same film as a film used for a source electrode and a drain electrode of the transistor 750 is connected to the upper electrode.

An insulating layer 770 that functions as a planarization film is provided over the transistor 750, the transistor 752, and the capacitor 790.

The transistor 750 in the display unit 702 and the transistor 752 in the circuit unit 763 may have different configurations. For example, a top-gate transistor may be used as one of the transistors 750 and 752, and a bottom-gate transistor may be used as the other. Note that this description as for the circuit unit 763 can be applied to the circuit unit 764.

The connection terminal 703a includes a portion of the wiring 704. It is preferred that the connection terminal 703a have a stacked-layer structure where a plurality of conductive films are stacked, as illustrated in FIG. 10, in which case the conductivity and mechanical strength of the connection terminal 703a are improved. The connection terminal 703a is electrically connected to the FPC 706 via a connection layer 780. As the connection layer 780, for example, an anisotropic conductive material or the like can be used.

The display device 700 includes the substrate 762 and a substrate 740, each of which functions as a support substrate. As the substrate 762 and the substrate 740, a glass substrate or a substrate having flexibility such as a plastic substrate can be used, for example.

As illustrated in FIG. 10, a stacked-layer structure from the substrate 762 to the substrate 740 is referred to as a film 721. A film 722 is attached to the substrate 740 with a bonding layer 720 provided therebetween. The bonding layer 720, the film 721, and the film 722 correspond to the bonding layer 21, the film 11, and the film 12 in Embodiment 1, respectively.

The transistor 750, the transistor 752, the capacitor 790, and the like are provided over an insulating layer 744. The substrate 762 and the insulating layer 744 are bonded to each other with a bonding layer 742.

The display device 700 includes a light-emitting element 782, a coloring layer 736, a light-blocking layer 738, and the like.

The light-emitting element 782 includes a conductive layer 772, an EL layer 786, and a conductive layer 788. The conductive layer 772 is electrically connected to the source electrode or the drain electrode included in the transistor 750. The conductive layer 772 is provided over the insulating layer 770 and functions as a pixel electrode. An insulating layer 730 is provided to cover an end portion of the conductive layer 772. Over the insulating layer 730 and the conductive layer 772, the EL layer 786 and the conductive layer 788 are stacked.

For the conductive layer 772, a material having a property of reflecting visible light can be used. For example, a material containing aluminum, silver, or the like can be used. For the conductive layer 788, a material that transmits visible light can be used. For example, an oxide material containing indium, zinc, tin, or the like is preferably used. Thus, the light-emitting element 782 is a top-emission light-emitting element, which emits light to the side opposite the formation surface (the substrate 740 side).

The EL layer 786 contains an organic compound or an inorganic compound such as quantum dots. The EL layer 786 contains a light-emitting material that exhibits light when current flows.

As the light-emitting material, a fluorescent material, a phosphorescent material, a thermally activated delayed fluorescence (TADF) material, an inorganic compound (e.g., a quantum dot material), or the like can be used. Examples of materials that can be used for quantum dots include a colloidal quantum dot material, an alloyed quantum dot material, a core-shell quantum dot material, and a core quantum dot material.

The light-blocking layer 738 and the coloring layer 736 are provided on one surface of an insulating layer 746. The coloring layer 736 is provided in a position overlapping with the light-emitting element 782. The light-blocking layer 738 is provided in a region not overlapping with the light-emitting element 782 in the display unit 702. The light-blocking layer 738 may also be provided to overlap with the circuit unit 763 or the like.

The substrate 740 is bonded to the other surface of the insulating layer 746 with a bonding layer 747. The substrate 740 and the substrate 762 are bonded to each other with a sealing layer 732.

Here, for the EL layer 786 included in the light-emitting element 782, a light-emitting material that exhibits white light emission is used. White light emission by the light-emitting element 782 is colored by the coloring layer 736 to be emitted to the outside. The EL layer 786 is provided over the pixels that exhibit different colors. The pixels provided with the coloring layer 736 transmitting any of red light (R), green light (G), and blue light (B) are arranged in a matrix in the display unit 702, whereby the display device 700 can perform full-color display.

A conductive film having a transmissive property and a reflective property may be used for the conductive layer 788. In this case, a microcavity structure is achieved between the conductive layer 772 and the conductive layer 788 such that light of a specific wavelength can be intensified to be emitted. Also in this case, an optical adjustment layer for adjusting an optical distance may be placed between the conductive layer 772 and the conductive layer 788 such that the thickness of the optical adjustment layer differs between pixels of different colors and accordingly the color purity of light emitted from each pixel can be increased.

Note that a configuration in which the coloring layer 736 or the above optical adjustment layer is not provided may be employed when the EL layer 786 is formed into an island shape for each pixel or into a stripe shape for each pixel column, i.e., the EL layer 786 is formed by separate coloring.

Here, an inorganic insulating film that functions as a barrier film having low permeability is preferably used for each of the insulating layer 744 and the insulating layer 746. With such a configuration in which the light-emitting element 782, the transistor 750, and the like are interposed between the insulating layer 744 and the insulating layer 746, deterioration of them can be inhibited and a highly reliable display device can be achieved.

### Configuration Example 2

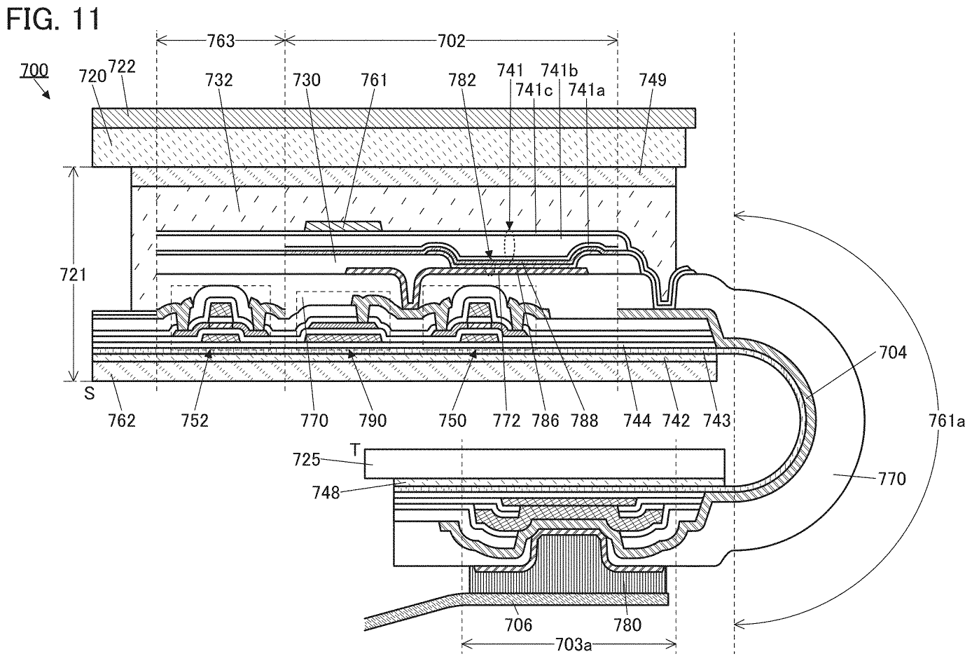

FIG. 11 is a cross-sectional view of the display device 700 having a configuration partly different from that of FIG. 10. Furthermore, FIG. 11 clearly shows an embodiment in which part of the display device 700 is bent in the bent portion 761a and folded back to the side opposite to the display surface side.

In the display device 700 shown in FIG. 11, a resin layer 743 is provided between the bonding layer 742 and the insulating layer 744 illustrated in FIG. 10. A protection layer 749 is provided instead of the substrate 740.

The resin layer 743 is a layer containing an organic resin such as polyimide or acrylic. The insulating layer 744 contains an inorganic insulating film such as silicon oxide, silicon oxynitride, silicon nitride, or the like. The resin layer 743 and the substrate 762 are attached to each other with the bonding layer 742. The resin layer 743 is preferably thinner than the substrate 762.

The protection layer 749 is attached to the sealing layer 732. A glass substrate, a resin film, or the like can be used as the protection layer 749. As the protection layer 749, an optical member such as a polarizing plate (including a circularly polarizing plate) or a scattering plate, an input device such as a touch sensor panel, or a structure in which two or more of the above are stacked may be employed.

Here, the stacked-layer structure from the substrate 762 to a protective layer 749 is referred to as the film 721. The film 722 is attached to the protective layer 749 with the bonding layer 720 provided therebetween.

The EL layer 786 included in the light-emitting element 782 is provided over the insulating layer 730 and the conductive layer 772 in an island shape. The EL layers 786 are formed separately so that respective subpixels emit light of different colors, whereby color display can be performed without use of the coloring layer 736.

A protective layer 741 is provided to cover the light-emitting element 782. The protective layer 741 has a function of preventing diffusion of impurities such as water into the light-emitting element 782. The protection layer 741 has a stacked-layer structure in which an insulating layer 741a, an insulating layer 741b, and an insulating layer 741c are stacked in this order from the conductive layer 788 side. In that case, it is preferable that inorganic insulating films with a high barrier property against impurities such as water be used as the insulating layer 741a and the insulating layer 741c, and an organic insulating film that functions as a planarization film be used as the insulating layer 741b. The protection layer 741 is preferably provided to extend also to the circuit unit 763 and the like.

An organic insulating film covering the transistor 750, the transistor 752, and the like is preferably formed in an island shape inward from the sealing layer 732. In other words, an end portion of the organic insulating film is preferably inward from the sealing layer 732 or in a region overlapping with an end portion of the sealing layer 732. FIG. 11 shows an example in which the insulating layer 770, the insulating layer 730, and the insulating layer 741b are processed into island shapes. The insulating layer 741c and the insulating layer 741a are provided in contact with each other in a portion overlapping with the sealing layer 732, for example. Thus, a surface of the organic insulating film covering the transistor 750 and the transistor 752 is not exposed to the outside of the sealing layer 732, whereby diffusion of water or hydrogen from the outside to the transistor 750 and the transistor 752 through the organic insulating film can be suitably prevented. This can reduce variations in electrical characteristics of the transistors, so that a display device with extremely high reliability can be fabricated.

In FIG. 11, the bent portion 761a includes a portion where the substrate 762, the bonding layer 742, and the inorganic insulating film such as the insulating layer 744 are not provided. The bent portion 761a has a configuration in which the insulating layer 770 including an organic material covers the wiring 704 so that the wiring 704 is not exposed. In the configuration illustrated in FIG. 11, the bent portion 761a has a stacked-layer structure in which the resin layer 743, the wiring 704, and the insulating layer 770 are stacked.

When a configuration is employed in which an inorganic insulating film is not provided if possible in the bent portion 761a and only a conductive layer containing a metal or an alloy and a layer containing an organic material are stacked, generation of cracks caused at bending can be prevented. When the substrate 762 is not provided in the bent portion 761a, part of the display device 700 can be bent with an extremely small radius of curvature.

In a region overlapping with the connection terminal 703a, a support 725 is bonded to the resin layer 743 with a bonding layer 748 positioned therebetween. A material having higher rigidity than the substrate 762 and the like can be used for the support 725. Alternatively, the support 725 may be part of a housing of an electronic device or part of a component placed in an electronic device.

In FIG. 11, a conductive layer 761 is provided over the protection layer 741. The conductive layer 761 can be used as a wiring or an electrode.

In the case where a touch sensor is provided so as to overlap with the display device 700, the conductive layer 761 can function as an electrostatic shielding film for preventing transmission of electrical noise to the touch sensor during pixel driving. In this case, the configuration in which a predetermined constant potential is applied to the conductive layer 761 can be employed.

Alternatively, the conductive layer 761 can be used as an electrode of the touch sensor, for example. This enables the display device 700 to function as a touch panel. For example, the conductive layer 761 can be used as an electrode or a wiring of a capacitive touch sensor. In this case, the conductive layer 761 can be used as a wiring or an electrode to which a sensor circuit is connected or a wiring or an electrode to which a sensor signal is input. When the touch sensor is formed over the light-emitting element 782 in this manner, the number of components can be reduced, and manufacturing cost of an electronic device or the like can be reduced.

The conductive layer 761 is preferably provided in a portion not overlapping with the light-emitting element 782. The conductive layer 761 can be provided in a position overlapping with the insulating layer 730, for example. Thus, a transparent conductive film with a relatively low conductivity does not have to be used for the conductive layer 761, and a metal or an alloy having high conductivity or the like can be used, so that the sensitivity of the sensor can be increased.

As the type of the touch sensor that can be formed of the conductive layer 761, a variety of types such as a resistive type, a surface acoustic wave type, an infrared type, an optical type, and a pressure-sensitive type can be used, without limitation to a capacitive type. Alternatively, two or more of these types may be combined and used.

### [Components]

Components such as a transistor that can be used in the display device will be described below.

### [Transistor]

The transistors each include a conductive layer functioning as a gate electrode, a semiconductor layer, a conductive layer functioning as a source electrode, a conductive layer functioning as a drain electrode, and an insulating layer functioning as a gate insulating layer.

Note that there is no particular limitation on the structure of the transistor included in the display device of one embodiment of the present invention. For example, a planar transistor may be employed, a staggered transistor may be employed, or an inverted staggered transistor may be employed. A top-gate or bottom-gate transistor structure may be employed. Alternatively, gate electrodes may be provided above and below a channel.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable that a single crystal semiconductor or a semiconductor having crystallinity be used, in which case deterioration of the transistor characteristics can be inhibited.

In particular, a transistor that uses a metal oxide film for a semiconductor layer where a channel is formed is described below.

As a semiconductor material used for the transistors, a metal oxide whose energy gap is greater than or equal to 2 eV, preferably greater than or equal to 2.5 eV, further preferably greater than or equal to 3 eV can be used. A typical example thereof is a metal oxide containing indium, and for example, a CAC-OS described later or the like can be used.

A transistor with a metal oxide having a larger band gap and a lower carrier density than silicon has a low off-state current; therefore, charges stored in a capacitor that is series-connected to the transistor can be held for a long time.

The semiconductor layer can be, for example, a film represented by an In-M-Zn-based oxide that contains indium, zinc, and M (M is a metal such as aluminum, titanium, gallium, germanium, yttrium, zirconium, lanthanum, cerium, tin, neodymium, or hafnium).

In the case where a metal oxide that constitutes the semiconductor layer is an In-M-Zn-based oxide, it is preferable that the atomic ratio of metal elements in a sputtering target used to deposit an In-M-Zn oxide satisfy In≥M and Zn≥M. The atomic ratio between metal elements in such a sputtering target is preferably, for example, In:M:Zn=1:1:1, In:M:Zn=1:1:1.2, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=10:1:3, or In:M:Zn=5:3:4. Note that the atomic ratio between metal elements in the formed semiconductor layer may vary from the above atomic ratio between metal elements in the sputtering target in a range of ±40%.

A metal oxide film with a low carrier density is used as the semiconductor layer. For example, for the semiconductor layer, a metal oxide whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³ can be used. Such a metal oxide is referred to as a highly purified intrinsic or substantially highly purified intrinsic metal oxide. The oxide semiconductor has a low density of defect states and thus can be regarded as a metal oxide having stable characteristics.

Note that, without limitation to these, an oxide semiconductor with an appropriate composition may be used in accordance with required semiconductor characteristics and electrical characteristics (e.g., field-effect mobility and threshold voltage) of the transistor. In addition, to obtain the required semiconductor characteristics of the transistor, it is preferable that the carrier density, impurity concentration, defect density, atomic ratio between a metal element and oxygen, interatomic distance, density, and the like of the semiconductor layer be set to be appropriate.

When silicon or carbon, which is one of the Group 14 elements, is contained in the metal oxide that constitutes the semiconductor layer, oxygen vacancies are increased, and the semiconductor layer becomes n-type. Thus, the concentration of silicon or carbon (measured by secondary ion mass spectrometry) in the semiconductor layer is set to 2×10¹⁸ atoms/cm³ or lower, preferably 2×10¹⁷ atoms/cm³ or lower.

Alkali metal and alkaline earth metal might generate carriers when bonded to a metal oxide, in which case the off-state current of the transistor might be increased. Thus, the concentration of alkali metal or alkaline earth metal in the semiconductor layer is set to lower than or equal to 1×10¹⁸ atoms/cm³, preferably lower than or equal to 2×10¹⁶ atoms/cm³.

Furthermore, when nitrogen is contained in the metal oxide that constitutes the semiconductor layer, electrons serving as carriers are generated and the carrier density is increased, so that the semiconductor layer easily becomes n-type. As a result, a transistor using a metal oxide that contains nitrogen is likely to have normally-on characteristics. Therefore, the concentration of nitrogen in the semiconductor layer, which is measured by secondary ion mass spectrometry, is preferably set to lower than or equal to 5×10¹⁸ atoms/cm³.

Oxide semiconductors (metal oxides) are classified into a single crystal oxide semiconductor and other non-single-crystal oxide semiconductors. Examples of the non-single-crystal oxide semiconductor include a CAAC-OS (c-axis aligned crystalline oxide semiconductor), a polycrystalline oxide semiconductor, an nc-OS (nanocrystalline oxide semiconductor), an amorphous-like oxide semiconductor (a-like OS), and an amorphous oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that it is difficult to observe a clear crystal grain boundary (also referred to as grain boundary) even in the vicinity of distortion in the CAAC-OS. That is, formation of a crystal grain boundary is found to be inhibited by the distortion of a lattice arrangement. This is because the CAAC-OS can tolerate distortion owing to a low density of arrangement of oxygen atoms in the a-b plane direction, an interatomic bond length changed by substitution of a metal element, and the like. Note that a crystal structure in which a clear grain boundary is observed is what is called polycrystal. It is highly probable that the grain boundary becomes a recombination center and traps carriers and thus decreases the on-state current and field-effect mobility of a transistor. Thus, the CAAC-OS in which no clear grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a grain boundary as compared with an In oxide.

The CAAC-OS tends to have a layered crystal structure (also referred to as a layered structure) in which a layer containing indium and oxygen (hereinafter, an In layer) and a layer containing the element M, zinc, and oxygen (hereinafter, an (M,Zn) layer) are stacked. Note that indium and the element M can be replaced with each other, and when the element M in the (M,Zn) layer is replaced with indium, the layer can also be referred to as an (In,M,Zn) layer. Furthermore, when indium in the In layer is replaced with the element M, the layer can be referred to as an (In,M) layer.

The CAAC-OS is a metal oxide with high crystallinity. On the other hand, a clear crystal grain boundary is difficult to observe in the CAAC-OS; thus, it can be said that a reduction in electron mobility due to the crystal grain boundary is unlikely to occur. Entry of impurities, formation of defects, or the like might decrease the crystallinity of a metal oxide, which means that the CAAC-OS is a metal oxide having small amounts of impurities and defects (e.g., oxygen vacancies). Thus, a metal oxide including a CAAC-OS is physically stable. Therefore, the metal oxide including a CAAC-OS is resistant to heat and has high reliability.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

Note that an In—Ga—Zn oxide (hereinafter, IGZO) that is a kind of metal oxide containing indium, gallium, and zinc has a stable structure in some cases by being formed of the above-described nanocrystals. In particular, crystals of IGZO tend not to grow in the air and thus, a stable structure is obtained when IGZO is formed of smaller crystals (e.g., the above-described nanocrystals) rather than larger crystals (here, crystals with a size of several millimeters or several centimeters).

An a-like OS is a metal oxide having a structure between those of the nc-OS and an amorphous oxide semiconductor. The a-like OS includes a void or a low-density region. That is, the a-like OS has low crystallinity compared with the nc-OS and the CAAC-OS.

An oxide semiconductor (metal oxide) can have various structures that show different properties. Two or more of the amorphous oxide semiconductor, the polycrystalline oxide semiconductor, the a-like OS, the nc-OS, and the CAAC-OS may be included in an oxide semiconductor of one embodiment of the present invention.

Note that the non-single-crystal oxide semiconductor can be suitably used for a semiconductor layer of a transistor disclosed in one embodiment of the present invention. As the non-single-crystal oxide semiconductor, the nc-OS or the CAAC-OS can be suitably used.

The semiconductor layer may be a mixed film including two or more of a region of a CAAC-OS, a region of a polycrystalline oxide semiconductor, a region of an nc-OS, a region of an amorphous-like oxide semiconductor, and a region of an amorphous oxide semiconductor. The mixed film has, for example, a single-layer structure or a layered structure including two or more of the foregoing regions in some cases.

A CAC-OS (Cloud-Aligned Composite oxide semiconductor) is preferably used for a semiconductor layer of a transistor disclosed in one embodiment of the present invention. The use of the CAC-OS allows the transistor to have high electrical characteristics or high reliability.

### <Composition of CAC-OS>

The composition of a CAC (Cloud-Aligned Composite)-OS that can be used in a transistor disclosed in one embodiment of the present invention will be described below.

A CAC-OS has a conducting function in part of the material and has an insulating function in another part of the material; as a whole, the CAC-OS has a function of a semiconductor. Note that in the case where the CAC-OS is used in an active layer of a transistor, the conducting function is a function that allows electrons (or holes) serving as carriers to flow, and the insulating function is a function that does not allow electrons serving as carriers to flow. By the complementary action of the conducting function and the insulating function, a switching function (On/Off function) can be given to the CAC-OS. In the CAC-OS, separation of the functions can maximize each function.

In addition, the CAC-OS includes conductive regions and insulating regions. The conductive regions have the above-described conducting function, and the insulating regions have the above-described insulating function. Furthermore, in some cases, the conductive regions and the insulating regions in the material are separated at the nanoparticle level. Furthermore, in some cases, the conductive regions and the insulating regions are unevenly distributed in the material. Furthermore, in some cases, the conductive regions are observed to be coupled in a cloud-like manner with their boundaries blurred.

In the CAC-OS, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

The CAC-OS is composed of components having different band gaps. For example, the CAC-OS is composed of a component having a wide gap due to the insulating region and a component having a narrow gap due to the conductive region. In the case of the structure, when carriers flow, carriers mainly flow in the component having a narrow gap. Furthermore, the component having a narrow gap complements the component having a wide gap, and carriers also flow in the component having a wide gap in conjunction with the component having a narrow gap. Therefore, in the case where the above-described CAC-OS is used in a channel formation region of a transistor, the transistor in the on state can achieve high current driving capability, that is, high on-state current and high field-effect mobility.

In other words, the CAC-OS can also be referred to as a matrix composite or a metal matrix composite.

Note that the metal oxide preferably contains at least indium. In particular, indium and zinc are preferably contained. In addition, one or more of aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like may be contained.

Note that a compound containing In, Ga, Zn, and O is also known as IGZO. Typical examples of IGZO include a crystalline compound represented by InGaO₃(ZnO)ₘ₁ (m1 is a natural number) and a crystalline compound represented by In₍₁₊ₓ₀₎Ga₍₁₋ₓ₀₎O₃(ZNO)ₘ₀ (−1≤x0≤1; m0 is a given number).

The above crystalline compounds have a single crystal structure, a polycrystalline structure, or a CAAC structure. Note that the CAAC structure is a crystal structure in which a plurality of IGZO nanocrystals have c-axis alignment and are connected in the a-b plane direction without alignment.

Meanwhile, the CAC-OS relates to the material composition of a metal oxide. In a material composition of a CAC-OS containing In, Ga, Zn, and O, nanoparticle regions containing Ga as a main component are observed in part of the CAC-OS and nanoparticle regions containing In as a main component are observed in part thereof. These nanoparticle regions are randomly dispersed to form a mosaic pattern. Therefore, the crystal structure is a secondary element for the CAC-OS.

In the case where one or more of aluminum, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like are contained instead of gallium in a CAC-OS, nanoparticle regions containing the selected metal element(s) as a main component(s) are observed in part of the CAC-OS and nanoparticle regions containing In as a main component are observed in part of the CAC-OS, and these nanoparticle regions are randomly dispersed to form a mosaic pattern in the CAC-OS.

The CAC-OS can be formed by a sputtering method under a condition where a substrate is not heated intentionally, for example. Moreover, in the case of forming the CAC-OS by a sputtering method, any one or more selected from an inert gas (typically, argon), an oxygen gas, and a nitrogen gas are used as a deposition gas. The flow rate of the oxygen gas to the total flow rate of the deposition gas in deposition is preferably as low as possible, for example, the flow rate of the oxygen gas is higher than or equal to 0% and lower than 30%, preferably higher than or equal to 0% and lower than or equal to 10%.

A semiconductor element using a CAC-OS has high reliability. Thus, the CAC-OS is suitably used in a variety of semiconductor devices typified by a display.

Since a transistor including a CAC-OS in a semiconductor layer has high field-effect mobility and high driving capability, the use of the transistor in a driver circuit, typically a scan line driver circuit that generates a gate signal, enables a display device with a narrow frame width (also referred to as a narrow bezel) to be provided. Furthermore, with the use of the transistor in a signal line driver circuit that is included in a display device (particularly in a demultiplexer connected to an output terminal of a shift register included in a signal line driver circuit), the display device connected to less number of wirings can be provided.

Furthermore, unlike a transistor including low-temperature polysilicon, the transistor including a CAC-OS in the semiconductor layer does not need a laser crystallization step. Thus, the manufacturing cost of a display device can be reduced, even when the display device is formed using a large substrate. In addition, the transistor including a CAC-OS in the semiconductor layer is preferably used for a driver circuit and a display unit in a large display device having high resolution such as ultra high definition (“4K resolution”, “4K2K”, and “4K”) or super high definition (“8K resolution”, “8K4K”, and “8K”), in which case writing can be performed in a short time and display defects can be reduced.

Oxide semiconductors might be classified in a manner different from the above-described one when classified in terms of the crystal structure. Here, the classification of the crystal structures of an oxide semiconductor is explained. As a typical example, the classification of crystal structures of IGZO (a metal oxide containing In, Ga, and Zn), is explained.

IGZO is roughly classified into “Amorphous”, “Crystalline”, and “Crystal”. Amorphous includes completely amorphous. Crystalline includes CAAC, nc, and CAC. Note that the term “Crystalline” excludes single crystal, poly crystal, and completely amorphous. Crystal includes single crystal and poly crystal.

Note that the structures classified as “Crystalline” are in an intermediate state between “Amorphous” and “Crystal”, and belong to a new crystalline phase. This structure is positioned in a boundary region between Amorphous and Crystal. In other words, these structures are completely different from “Amorphous”, which is energetically unstable, and “Crystal”.

A crystal structure of a film or a substrate can be analyzed with X-ray diffraction (XRD) images.

As an example, the XRD spectrum of quartz glass shows a peak with a substantially bilaterally symmetrical shape. By contrast, the XRD spectrum of crystalline IGZO shows a peak with an asymmetrical shape. The asymmetrical peak of the XRD spectrum clearly shows the existence of crystal. In other words, the structure cannot be regarded as Amorphous unless it has a bilaterally symmetrical peak in the XRD spectrum. Note that the asymmetrical shape of the peak of the XRD spectrum of crystalline IGZO is presumably attributed to the crystal phase (microcrystal).

Specifically, in the XRD spectrum of crystalline IGZO, there is a peak at 2θ=34° or in the neighborhood thereof. The microcrystal has a peak at 2θ=31° or in the neighborhood thereof. When an oxide semiconductor film is evaluated using an X-ray diffraction pattern, the spectrum becomes wide in the lower degree side than the peak at 2θ=34° or in the neighborhood thereof. This indicates that the oxide semiconductor film includes a microcrystal attributed to a peak at 2θ=31° or in the neighborhood thereof.

A crystal structure of a film can also be evaluated with a diffraction pattern obtained by a nanobeam electron diffraction (NBED) method (also referred to as nanobeam electron diffraction pattern). In the nanobeam electron diffraction method, electron diffraction is performed with a probe diameter of 1 nm, for example. In the diffraction pattern of the IGZO film formed by sputtering with the substrate temperature being at room temperature, not a halo pattern but a spot-like pattern is observed. Thus, it is presumed that the IGZO film formed at room temperature is in an intermediate state, which is neither a crystal state nor an amorphous state, and it cannot be concluded that the IGZO film is in an amorphous state.

Alternatively, silicon may be used for a semiconductor in which a channel of a transistor is formed. As the silicon, amorphous silicon may be used but silicon having crystallinity is preferably used. For example, microcrystalline silicon, polycrystalline silicon, or single-crystal silicon are preferably used. In particular, polycrystalline silicon can be formed at a temperature lower than that for single crystal silicon and has higher field-effect mobility and higher reliability than amorphous silicon.

### [Conductive Layer]

Examples of materials that can be used for conductive layers of a variety of wirings and electrodes and the like included in the display device in addition to a gate, a source, and a drain of a transistor include metals such as aluminum, titanium, chromium, nickel, copper, yttrium, zirconium, molybdenum, silver, tantalum, and tungsten and an alloy containing such a metal as its main component. A single-layer structure or stacked-layer structure including a film containing any of these materials can be used. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, a three-layer structure in which an aluminum film or a copper film is stacked over a molybdenum film or a molybdenum nitride film and a molybdenum film or a molybdenum nitride film is formed thereover, and the like can be given. Note that an oxide such as indium oxide, tin oxide, or zinc oxide may be used. Furthermore, copper containing manganese is preferably used because it increases controllability of a shape by etching.

### [Insulating Layer]

Examples of an insulating material that can be used for the insulating layers include, in addition to a resin such as acrylic or epoxy and a resin having a siloxane bond, an inorganic insulating material such as silicon oxide, silicon oxynitride, silicon nitride oxide, silicon nitride, or aluminum oxide.

The light-emitting element is preferably provided between a pair of insulating films with low water permeability. In that case, impurities such as water can be inhibited from entering the light-emitting element, and thus a decrease in device reliability can be inhibited.

Examples of the insulating film with low water permeability include a film containing nitrogen and silicon, such as a silicon nitride film and a silicon nitride oxide film, and a film containing nitrogen and aluminum, such as an aluminum nitride film. Alternatively, a silicon oxide film, a silicon oxynitride film, an aluminum oxide film, or the like may be used.

For example, the moisture vapor transmission rate of the insulating film with low water permeability is lower than or equal to 1×10⁻⁵ [g/(m²·day)], preferably lower than or equal to 1×10⁻⁶ [g/(m²·day)], further preferably lower than or equal to 1×10⁻⁷ [g/(m²·day)], still further preferably lower than or equal to 1×10⁻⁸ [g/(m²·day)].

The above is the description of the components.

At least part of the configuration examples, the drawings corresponding thereto, and the like exemplified in this embodiment can be implemented in combination with the other configuration examples, the other drawings, and the like as appropriate.

At least part of this embodiment can be implemented in combination with the other embodiments described in this specification as appropriate.

### Embodiment 3

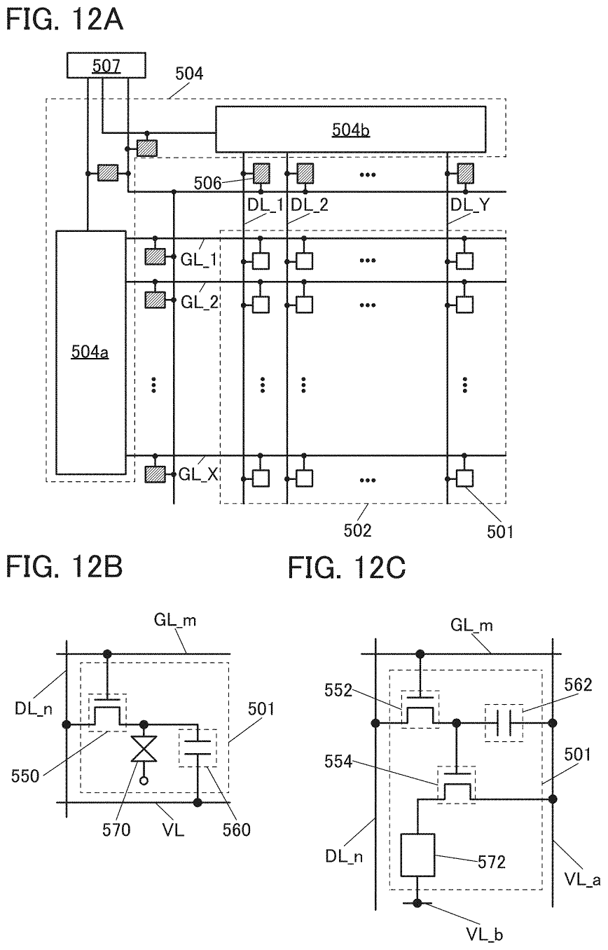

In this embodiment, configuration examples of a display device will be described with reference to FIG. 12.

The display device illustrated in FIG. 12A includes a pixel unit 502, a driver circuit unit 504, protection circuits 506, and a terminal portion 507. Note that a configuration in which the protection circuits 506 are not provided may be employed.

The pixel unit 502 includes a plurality of pixel circuits 501 arranged in X rows and Y columns (X and Y each independently represent a natural number of 2 or more). Each of the pixel circuits 501 includes a circuit that drives a display element.

The driver circuit unit 504 includes driver circuits such as a gate driver 504a that outputs a scanning signal to gate lines GL_1 to GL_X and a source driver 504b that supplies a data signal to data lines DL_1 to DL_Y. The gate driver 504a includes at least a shift register. The source driver 504b is formed using a plurality of analog switches, for example. Alternatively, the source driver 504b may be formed using a shift register or the like.

The terminal portion 507 refers to a portion provided with terminals for inputting power, control signals, image signals, and the like to the display device from external circuits.

The protection circuit 506 is a circuit that, when a potential out of a certain range is applied to a wiring to which the protection circuit 506 is connected, establishes continuity between the wiring and another wiring. The protection circuit 506 illustrated in FIG. 12A is connected to a variety of wirings such as the gate lines GL that are wirings between the gate driver 504a and the pixel circuits 501 and the data lines DL that are wirings between the source driver 504b and the pixel circuits 501, for example. Note that the protection circuits 506 are hatched in FIG. 12A to distinguish the protection circuits 506 from the pixel circuits 501.

The gate driver 504a and the source driver 504b may be provided over a substrate over which the pixel unit 502 is provided, or a substrate where a gate driver circuit or a source driver circuit is separately formed (e.g., a driver circuit board formed using a single crystal semiconductor or a polycrystalline semiconductor) may be mounted on the substrate by COG or TAB (Tape Automated Bonding).

FIG. 12B and FIG. 12C each show an example of a configuration of a pixel circuit that can be used in the pixel circuit 501.

The pixel circuit 501 illustrated in FIG. 12B includes a liquid crystal element 570, a transistor 550, and a capacitor 560. The data line DL_n, the gate line GL_m, a potential supply line VL, and the like are connected to the pixel circuit 501.

The potential of one of a pair of electrodes of the liquid crystal element 570 is set appropriately in accordance with the specifications of the pixel circuit 501. The alignment state of the liquid crystal element 570 is set depending on written data. Note that a common potential may be supplied to one of the pair of electrodes of the liquid crystal element 570 included in each of the plurality of pixel circuits 501. Moreover, a different potential may be supplied to one of the pair of electrodes of the liquid crystal element 570 of the pixel circuit 501 in each row.

The pixel circuit 501 illustrated in FIG. 12C includes a transistor 552, a transistor 554, a capacitor 562, and a light-emitting element 572. The data line DL_n, the gate line GL_m, a potential supply line VL_a, a potential supply line VL_b, and the like are connected to the pixel circuit 501.

Note that a high power supply potential VDD is supplied to one of the potential supply line VL_a and the potential supply line VL_b, and a low power supply potential VSS is supplied to the other. Current flowing through the light-emitting element 572 is controlled in accordance with a potential applied to a gate of the transistor 554, whereby the luminance of light emitted from the light-emitting element 572 is controlled.

At least part of the configuration examples, the drawings corresponding thereto, and the like exemplified in this embodiment can be implemented in combination with the other configuration examples, the other drawings, and the like as appropriate.

At least part of this embodiment can be implemented in combination with the other embodiments described in this specification as appropriate.

### Embodiment 4

A pixel circuit including a memory for correcting gray levels displayed by pixels and a display device including the pixel circuit will be described below.

### [Circuit Configuration]

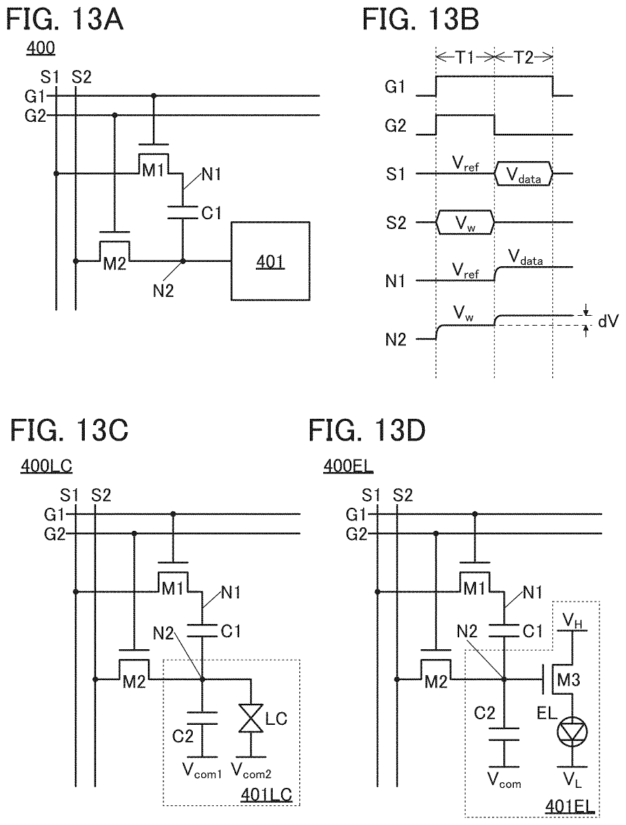

FIG. 13A shows a circuit diagram of a pixel circuit 400. The pixel circuit 400 includes a transistor M1, a transistor M2, a capacitor C1, and a circuit 401. A wiring S1, a wiring S2, a wiring G1, and a wiring G2 are connected to the pixel circuit 400.

In the transistor M1, a gate is connected to the wiring G1, one of a source and a drain is connected to the wiring S1, and the other is connected to one electrode of the capacitor C1. In the transistor M2, a gate is connected to the wiring G2, one of a source and a drain is connected to the wiring S2, and the other is connected to the other electrode of the capacitor C1 and the circuit 401.

The circuit 401 is a circuit including at least one display element. Any of a variety of elements can be used as the display element, and typically, a light-emitting element such as an organic EL element or an LED element, a liquid crystal element, a MEMS (Micro Electro Mechanical Systems) element, or the like can be used.

A node connecting the transistor M1 and the capacitor C1 is denoted as a node N1, and a node connecting the transistor M2 and the circuit 401 is denoted as a node N2.

In the pixel circuit 400, the potential of the node N1 can be retained when the transistor M1 is turned off. The potential of the node N2 can be retained when the transistor M2 is turned off. When a predetermined potential is written to the node N1 through the transistor M1 with the transistor M2 being in an off state, the potential of the node N2 can be changed in accordance with displacement in the potential of the node N1 owing to capacitive coupling through the capacitor C1.

Here, the transistor using an oxide semiconductor that is described in Embodiment 1 can be used as one or both of the transistor M1 and the transistor M2. Accordingly, owing to an extremely low off-state current, the potentials of the node N1 and the node N2 can be retained for a long time. Note that in the case where the period in which the potential of each node is retained is short (specifically, the case where the frame frequency is higher than or equal to 30 Hz, for example), a transistor using a semiconductor such as silicon may be used.

### [Driving Method Example]

Next, an example of a method of operating the pixel circuit 400 is described with reference to FIG. 13B. FIG. 13B is a timing chart of the operation of the pixel circuit 400. Note that for simplification of description, the influence of various kinds of resistance such as wiring resistance, parasitic capacitance of a transistor, a wiring, or the like, the threshold voltage of the transistor, and the like is not taken into account here.

In the operation shown in FIG. 13B, one frame period is divided into a period T1 and a period T2. The period T1 is a period in which a potential is written to the node N2, and the period T2 is a period in which a potential is written to the node N1.

### [Period T1]

In the period T1, a potential for turning on the transistor is supplied to both the wiring G1 and the wiring G2. In addition, a potential V_{ref} that is a fixed potential is supplied to the wiring S1, and a first data potential V_{w} is supplied to the wiring S2.

The potential V_{ref} is supplied from the wiring S1 to the node N1 through the transistor M1. The first data potential V_{w} is supplied from the wiring S2 to the node N2 through the transistor M2. Accordingly, a potential difference V_{w}−V_{ref} is retained in the capacitor C1.

### [Period T2]

Next, in the period T2, a potential for turning on the transistor M1 is supplied to the wiring G1, and a potential for turning off the transistor M2 is supplied to the wiring G2. A second data potential V_{data} is supplied to the wiring S1. The wiring S2 may be supplied with a predetermined constant potential or brought into a floating state.

The second data potential V_{data} is supplied from the wiring S1 to the node N1 through the transistor M1. At this time, capacitive coupling due to the capacitor C1 changes the potential of the node N2 in accordance with the second data potential V_{data} by a potential dV. That is, a potential that is the sum of the first data potential V_{w} and the potential dV is input to the circuit 401. Note that although dV is shown as a positive value in FIG. 13B, dV may be a negative value. That is, the second data potential V_{data} may be lower than the potential V_{ref}.

Here, the potential dV is roughly determined by the capacitance of the capacitor C1 and the capacitance of the circuit 401. When the capacitance of the capacitor C1 is sufficiently larger than the capacitance of the circuit 401, the potential dV is a potential close to the second data potential Vaasa.

In the above manner, the pixel circuit 400 can generate a potential to be supplied to the circuit 401 including the display element, by combining two kinds of data signals; hence, a gray level can be corrected in the pixel circuit 400.

The pixel circuit 400 can also generate a potential exceeding the maximum potential that can be supplied to the wiring S1 and the wiring S2. For example, in the case where a light-emitting element is used, high-dynamic range (HDR) display or the like can be performed. In the case where a liquid crystal element is used, overdriving or the like can be achieved.

### Application Examples

### [Example Using Liquid Crystal Element]

A pixel circuit 400LC illustrated in FIG. 13C includes a circuit 401LC. The circuit 401LC includes a liquid crystal element LC and a capacitor C2.

In the liquid crystal element LC, one electrode is connected to the node N2 and one electrode of the capacitor C2, and the other electrode is connected to a wiring supplied with a potential V_{com2}. The other electrode of the capacitor C2 is connected to a wiring supplied with a potential V_{com1}.

The capacitor C2 functions as a storage capacitor. Note that the capacitor C2 can be omitted when not needed.

In the pixel circuit 400LC, a high voltage can be supplied to the liquid crystal element LC; thus, high-speed display can be performed by overdriving or a liquid crystal material with a high driving voltage can be employed, for example. Moreover, by supply of a correction signal to the wiring S1 or the wiring S2, a gray level can be corrected in accordance with the operating temperature, the deterioration state of the liquid crystal element LC, or the like.

### [Example Using Light-Emitting Element]

A pixel circuit 400EL illustrated in FIG. 13D includes a circuit 401EL. The circuit 401EL includes a light-emitting element EL, a transistor M3, and the capacitor C2.

In the transistor M3, a gate is connected to the node N2 and one electrode of the capacitor C2, one of a source and a drain is connected to a wiring supplied with a potential V_{H}, and the other is connected to one electrode of the light-emitting element EL. The other electrode of the capacitor C2 is connected to a wiring supplied with a potential V_{com}. The other electrode of the light-emitting element EL is connected to a wiring supplied with a potential V_{L}.

The transistor M3 has a function of controlling a current to be supplied to the light-emitting element EL. The capacitor C2 functions as a storage capacitor. The capacitor C2 can be omitted when not needed.

Note that although the configuration in which the anode side of the light-emitting element EL is connected to the transistor M3 is described here, the transistor M3 may be connected to the cathode side. In that case, the values of the potential V_{H} and the potential V_{L} can be appropriately changed.

In the pixel circuit 400EL, a large amount of current can flow through the light-emitting element EL when a high potential is applied to the gate of the transistor M3, which enables HDR display, for example. Moreover, a variation in the electrical characteristics of the transistor M3 and the light-emitting element EL can be corrected by supply of a correction signal to the wiring S1 or the wiring S2.

Note that the configuration is not limited to the circuits illustrated in FIG. 13C and FIG. 13D, and a configuration to which a transistor, a capacitor, or the like is further added may be employed.

At least part of this embodiment can be implemented in combination with the other embodiments described in this specification as appropriate.

### Embodiment 5

Configuration examples of the pixel of the display panel of one embodiment of the present invention will be described below.

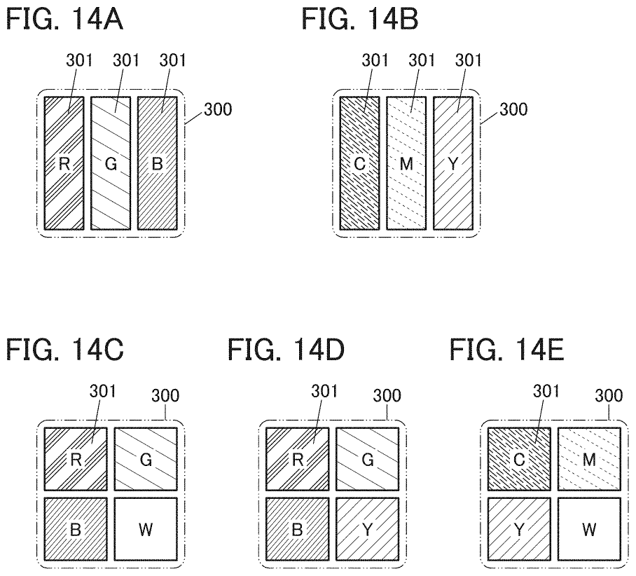

Structure examples of a pixel 300 are shown in FIG. 14A to FIG. 14E.

The pixel 300 includes a plurality of pixels 301. The plurality of pixels 301 each function as a subpixel. One pixel 300 is formed of the plurality of pixels 301 exhibiting different colors, and thus full-color display can be achieved in a display unit.

The pixels 300 illustrated in FIG. 14A and FIG. 14B each include three subpixels. The combination of colors exhibited by the pixels 301 included in the pixel 300 illustrated in FIG. 14A is red (R), green (G), and blue (B). The combination of colors exhibited by the pixels 301 included in the pixel 300 illustrated in FIG. 14B is cyan (C), magenta (M), and yellow (Y).

The pixels 300 illustrated in FIG. 14C to FIG. 14E each include four subpixels. The combination of colors exhibited by the pixels 301 included in the pixel 300 illustrated in FIG. 14C is red (R), green (G), blue (B), and white (W). The use of the subpixel that exhibits white can increase the luminance of the display unit. The combination of colors exhibited by the pixels 301 included in the pixel 300 illustrated in FIG. 14D is red (R), green (G), blue (B), and yellow (Y). The combination of colors exhibited by the pixels 301 included in the pixel 300 illustrated in FIG. 14E is cyan (C), magenta (M), yellow (Y), and white (W).

When subpixels that exhibit red, green, blue, cyan, magenta, yellow, and the like are combined as appropriate with more subpixels functioning as one pixel, the reproducibility of halftones can be increased. Thus, the display quality can be improved.

The display device of one embodiment of the present invention can reproduce the color gamut of various standards. For example, the display device of one embodiment of the present invention can reproduce the color gamut of the following standards: the PAL (Phase Alternating Line) or NTSC (National Television System Committee) standard used for TV broadcasting; the sRGB (standard RGB) or Adobe RGB standard used widely for display devices in electronic devices such as personal computers, digital cameras, and printers; the ITU-R BT.709 (International Telecommunication Union Radiocommunication Sector Broadcasting Service (Television) 709) standard used for HDTV (High Definition Televisions, also referred to Hi-Vision); the DCI-P3 (Digital Cinema Initiatives P3) standard used for digital cinema projection; and the ITU-R BT.2020 (REC.2020 (Recommendation 2020)) standard used for UHDTV (Ultra High Definition Television, also referred to as Super Hi-Vision); and the like.

Using the pixels 300 arranged in a matrix of 1920×1080, a display device that can achieve full color display with a resolution of what is called full high definition (also referred to as “2K resolution”, “2K1K”, “2K”, or the like) can be obtained. For example, using the pixels 300 arranged in a matrix of 3840×2160, a display device that can achieve full color display with a resolution of what is called ultra high definition (also referred to as “4K resolution”, “4K2K”, “4K”, or the like) can be obtained. For example, using the pixels 300 arranged in a matrix of 7680×4320, a display device that can achieve full color display with a resolution of what is called super high definition (also referred to as “8K resolution”, “8K4K”, “8K”, or the like) can be obtained. By increasing the number of pixels 300, a display device that can achieve full color display with 16K or 32K resolution can be achieved.

At least part of this embodiment can be implemented in combination with the other embodiments described in this specification as appropriate.

### Embodiment 6

In this embodiment, examples of an electronic device for which the display device of one embodiment of the present invention can be used are described.

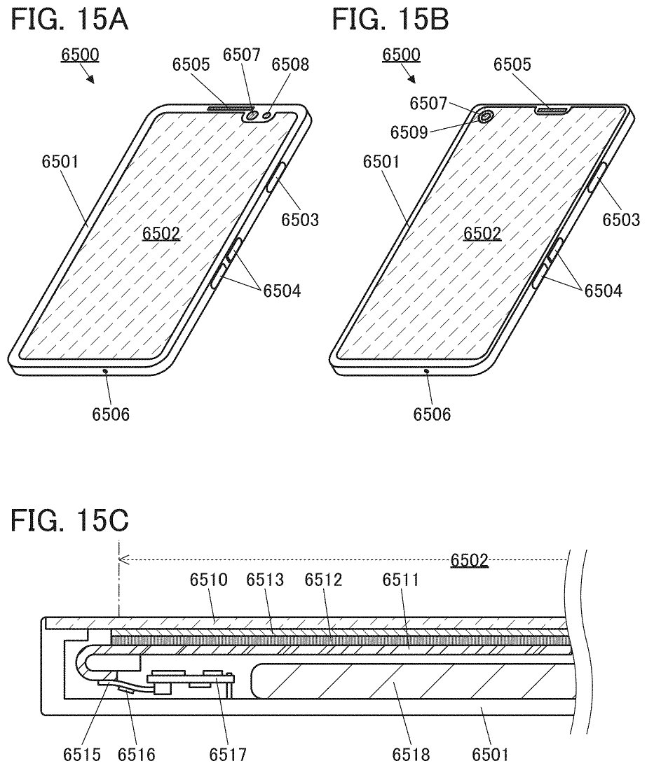

An electronic device 6500 illustrated in FIG. 15A is a portable information terminal that can be used as a smartphone.

The electronic device 6500 includes a housing 6501, a display unit 6502, a power button 6503, buttons 6504, a speaker 6505, a microphone 6506, a camera 6507, a light source 6508, and the like. The display unit 6502 has a touch panel function.

The display device of one embodiment of the present invention can be used in the display unit 6502.

The display unit 6502 has a notch, and the camera 6507 and the light source 6508 are provided to be engaged with the notch. With such a structure, an area occupied by the display unit 6502 with respect to the housing 6501 can be large.

Moreover, FIG. 15B shows an example in which the display unit 6502 has an opening, and the camera 6507 and an annular light source 6509 surrounding the camera 6507 are placed in the opening. Furthermore, the speaker 6505 is provided to be engaged with the notch of the display unit 6502. The display unit 6502 may be used as a light source that illuminates a subject. With such a structure, an area occupied by the display unit 6502 with respect to the housing 6501 can be large.

FIG. 15C is a schematic cross-sectional view including an end portion of the housing 6501 on the microphone 6506 side.

A protective member 6510 having a light-transmitting property is provided on the display surface side of the housing 6501, and a display panel 6511, an optical member 6512, a touch sensor panel 6513, a printed circuit board 6517, a battery 6518, and the like are provided in a space surrounded by the housing 6501 and the protective member 6510.

The display panel 6511, the optical member 6512, and the touch sensor panel 6513 are fixed to the protective member 6510 with a bonding layer not illustrated.

Part of the display panel 6511 is bent in a region outside the display unit 6502. An FPC 6515 is connected to the bent part. An IC 6516 is mounted on the FPC 6515. The FPC 6515 is connected to a terminal provided for the printed circuit board 6517.

A flexible display panel of one embodiment of the present invention can be used as the display panel 6511. Thus, an extremely lightweight electronic device can be achieved. Furthermore, since the display panel 6511 is extremely thin, the battery 6518 with a high capacity can be provided without an increase in the thickness of the electronic device. Moreover, part of the display panel 6511 is bent to provide a connection portion with the FPC 6515 on the back side of the pixel portion, whereby an electronic device with a narrow bezel can be obtained.

At least part of this embodiment can be implemented in combination with the other embodiments described in this specification as appropriate.

### Embodiment 7

In this embodiment, electronic devices each including a display device manufactured using one embodiment of the present invention are described.

Electronic devices exemplified below include a display device of one embodiment of the present invention in a display unit. Thus, the electronic devices achieve high resolution. In addition, the electronic devices can achieve both high resolution and a large screen.

The display unit of the electronic device of one embodiment of the present invention can display an image with a resolution of, for example, full high definition, 4K2K, 8K4K, 16K8K, or higher.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a laptop personal computer, a monitor device, digital signage, a pachinko machine, or a game machine.

The electronic device using one embodiment of the present invention can be incorporated along a flat surface or a curved surface of an inside wall or an outside wall of a house or a building, an interior or an exterior of a car, or the like.

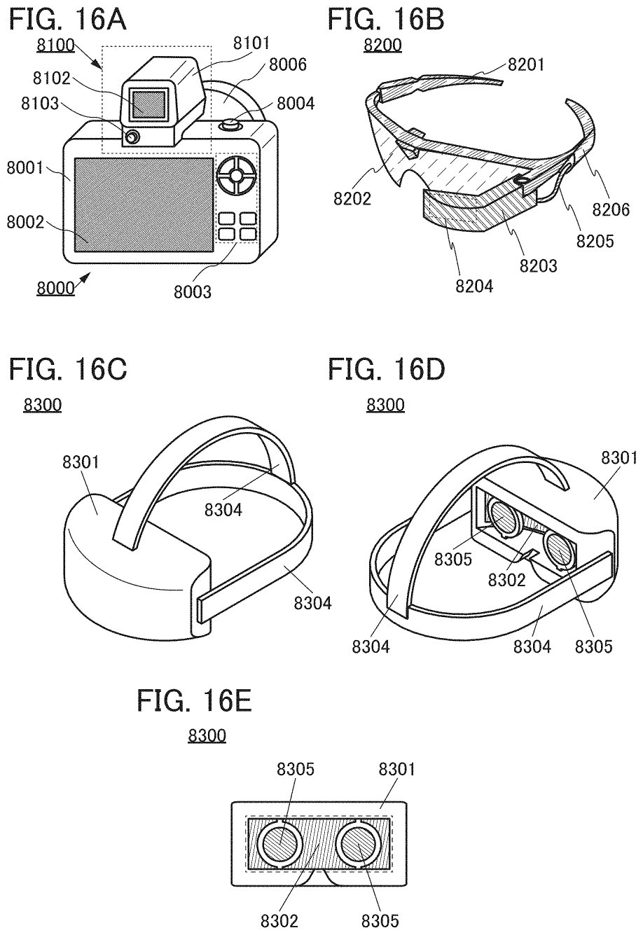

FIG. 16A is a diagram showing appearance of a camera 8000 to which a finder 8100 is attached.

The camera 8000 includes a housing 8001, a display unit 8002, operation buttons 8003, a shutter button 8004, and the like. A detachable lens 8006 is attached to the camera 8000.

Note that the lens 8006 and the housing may be integrated with each other in the camera 8000.

The camera 8000 can take images by the press of the shutter button 8004 or touch on the display unit 8002 serving as a touch panel.

The housing 8001 includes a mount including an electrode, so that, in addition to the finder 8100, a stroboscope or the like can be connected to the housing.

The finder 8100 includes a housing 8101, a display unit 8102, a button 8103, and the like.

The housing 8101 is attached to the camera 8000 with a mount engaging with a mount of the camera 8000. The finder 8100 can display an image or the like received from the camera 8000 on the display unit 8102.

The button 8103 serves as a power button or the like.

The display unit 8002 of the camera 8000 and the display unit 8102 of the finder 8100 can use the display device of one embodiment of the present invention. Note that a finder may be incorporated in the camera 8000.

FIG. 16B is a diagram showing appearance of a head-mounted display 8200.

The head-mounted display 8200 includes a mounting portion 8201, a lens 8202, a main body 8203, a display unit 8204, a cable 8205, and the like. A battery 8206 is incorporated in the mounting portion 8201.

The cable 8205 supplies electric power from the battery 8206 to the main body 8203. The main body 8203 includes a wireless receiver or the like and can display received image data on the display unit 8204. The main body 8203 is provided with a camera, and data on the movement of the user's eyeball and eyelid can be used as an input means.

The mounting portion 8201 may include a plurality of electrodes capable of sensing current flowing in response to the movement of the user's eyeball in a position in contact with the user to achieve a function of recognizing the user's sight line. A function of monitoring the user's pulse with the use of current flowing through the electrodes may be achieved. The mounting portion 8201 may include various sensors such as a temperature sensor, a pressure sensor, and an acceleration sensor to have a function of displaying the user's biological information on the display unit 8204 or a function of changing an image displayed on the display unit 8204 in accordance with the movement of the user's head.

The display unit 8204 can use the display device of one embodiment of the present invention.

FIG. 16C, FIG. 16D, and FIG. 16E are diagrams showing appearance of a head-mounted display 8300. The head-mounted display 8300 includes a housing 8301, a display unit 8302, a band-shaped fixing unit 8304, and a pair of lenses 8305.

A user can see display on the display unit 8302 through the lenses 8305. Note that the display unit 8302 is preferably curved and placed, in which case the user can feel a high realistic sensation. When another image displayed in a different region of the display unit 8302 is viewed through the lenses 8305, three-dimensional display using parallax or the like can also be performed. Note that the configuration is not limited to that in which one display unit 8302 is provided, and two display units 8302 may be provided so that one display unit is provided for one eye of the user.

Note that the display device of one embodiment of the present invention can be used in the display unit 8302. The display device including the semiconductor device of one embodiment of the present invention has an extremely high resolution; thus, even when an image is magnified using the lenses 8305 as in FIG. 16E, the user does not perceive pixels, and a more realistic image can be displayed.

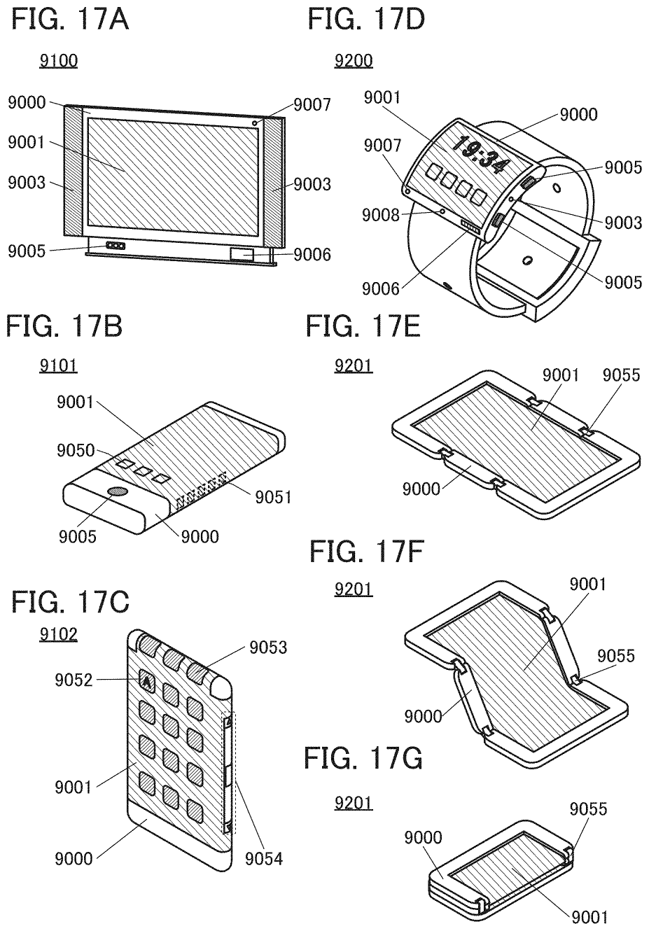

Electronic devices illustrated in FIG. 17A to FIG. 17G include a housing 9000, a display unit 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 17A to FIG. 17G have a variety of functions. For example, the electronic devices can have a function of displaying a variety of data (a still image, a moving image, a text image, and the like) on the display unit, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display units. The electronic devices may each include a camera or the like and have a function of taking a still image or a moving image and storing the taken image in a recording medium (external or incorporated in the camera), a function of displaying the taken image on the display unit, or the like.

The details of the electronic devices illustrated in FIG. 17A to FIG. 17G are described below.

FIG. 17A is a perspective view showing a television device 9100. The television device 9100 can include the display unit 9001 having a large screen size of, for example, 50 inches or more, or 100 inches or more.

FIG. 17B is a perspective view showing a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 17B shows an example in which three icons 9050 are displayed. Information 9051 indicated by dashed rectangles can be displayed on another surface of the display unit 9001. Examples of the information 9051 include notification of reception of an e-mail, SNS, or an incoming call, the title and sender of an e-mail, SNS, or the like, the date, the time, remaining battery, and the reception strength of an antenna. Alternatively, the icon 9050 or the like may be displayed in the position where the information 9051 is displayed.

FIG. 17C is a perspective view showing a portable information terminal 9102. The portable information terminal 9102 has a function of displaying information on three or more surfaces of the display unit 9001. Here, an example in which information 9052, information 9053, and information 9054 are displayed on different surfaces is shown. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 17D is a perspective view showing a watch-type portable information terminal 9200. The display surface of the display unit 9001 is curved and provided, and display can be performed along the curved display surface. Mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 17E, FIG. 17F, and FIG. 17G are perspective views showing a foldable portable information terminal 9201. FIG. 17E is a perspective view of an opened state of the portable information terminal 9201, FIG. 17G is a perspective view of a folded state thereof, and FIG. 17F is a perspective view of a state in the middle of change from one of FIG. 17E and FIG. 17G to the other. The portable information terminal 9201 is highly portable in the folded state and is highly browsable in the opened state because of a seamless large display region. The display unit 9001 of the portable information terminal 9201 is supported by three housings 9000 joined by hinges 9055. For example, the display unit 9001 can be folded with a radius of curvature of greater than or equal to 1 mm and less than or equal to 150 mm.

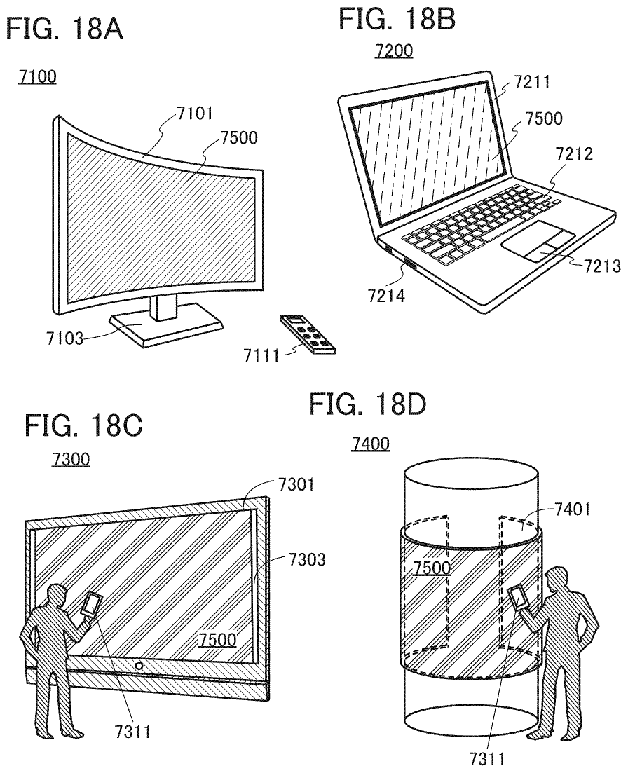

FIG. 18A shows an example of a television device. In a television device 7100, a display unit 7500 is incorporated in a housing 7101. Here, a structure in which the housing 7101 is supported by a stand 7103 is illustrated.

Operation of the television device 7100 illustrated in FIG. 18A can be performed with an operation switch provided in the housing 7101 or a separate remote controller 7111. Alternatively, a touch panel may be used for the display unit 7500, and the television device 7100 may be operated by touch on the touch panel. The remote controller 7111 may be provided with a display unit in addition to operation buttons.

Note that the television device 7100 may include a television receiver and a communication device for a network connection.

FIG. 18B illustrates a laptop personal computer 7200. The laptop personal computer 7200 includes a housing 7211, a keyboard 7212, a pointing device 7213, an external connection port 7214, and the like. In the housing 7211, the display unit 7500 is incorporated.

FIG. 18C and FIG. 18D show examples of digital signage.

Digital signage 7300 illustrated in FIG. 18C includes a housing 7301, the display unit 7500, a speaker 7303, and the like. Furthermore, the digital signage can include an LED lamp, operation keys (including a power switch or an operation switch), a connection terminal, a variety of sensors, a microphone, and the like.

FIG. 18D illustrates digital signage 7400 attached to a cylindrical pillar 7401. The digital signage 7400 includes the display unit 7500 provided along a curved surface of the pillar 7401.

The larger display unit 7500 can increase the amount of data that can be provided at a time and attracts more attention, so that the effectiveness of the advertisement can be increased, for example.

A touch panel is preferably used in the display unit 7500 so that the user can operate the digital signage. Thus, the digital signage can be used for not only advertising but also providing information that the user needs, such as route information, traffic information, and an information map of a commercial facility.

As illustrated in FIG. 18C and FIG. 18D, it is preferable that the digital signage 7300 or the digital signage 7400 be capable of working with an information terminal 7311 such as user's smartphone through wireless communication. For example, information of an advertisement displayed on the display unit 7500 can be displayed on a screen of the information terminal 7311. By operation of the information terminal 7311, display on the display unit 7500 can be switched.

It is possible to make the digital signage 7300 or the digital signage 7400 execute a game with the use of the information terminal 7311 as an operation means (controller). Thus, an unspecified number of users can join in and enjoy the game concurrently.

The display device of one embodiment of the present invention can be used in the display unit 7500 in FIG. 18A to FIG. 18D.

### Example

In this example, samples with varied stacked-layer structures were fabricated, and the results of measuring tensile modulus of elasticity and bending modulus of elasticity of the samples will be described.

### [Evaluation 1]

### [Samples]

In this example, a 100-μm-thick PEN (Polyethylene naphthalate) film was used as a film simulating the film 11 and the film 12 described in Embodiment 1 above. In addition, a silicone gel sheet was used as a viscoelastic sheet simulating the bonding layer 21.

Table 1 shows the stacked-layer structures of five samples that were fabricated and the thickness of each layer.

TABLE 1

| Sample | | |
|---|---|---|
| name | Stacked-layer structure | Thickness |
| Ref. 1 | PEN | 100 μm |
| Ref. 2 | PEN/epoxy resin/PEN | 100 μm/10 μm/100 μm |
| A1 | PEN/viscoelastic sheet/PEN | 100 μm/300 μm/100 μm |
| A2 | PEN/viscoelastic sheet/PEN | 100 μm/500 μm/100 μm |
| A3 | PEN/viscoelastic sheet/PEN | 100 μm/1000 μm/100 μm |

A sample A1, a sample A2, and a sample A3 each have a configuration where a pair of PEN films are attached to each other with the viscoelastic sheet. The thickness of the viscoelastic sheet is changed between the sample A1, the sample A2, and the sample A3 to increase in this order.

As comparative samples, a comparative sample Ref 1 and a comparative sample Ref 2 were fabricated. The comparative sample Ref 1 is a single PEN film. The comparative sample Ref 2 is a pair of PEN films attached to each other with an adhesive whose main component is an epoxy resin. As the epoxy resin, a two-component-type epoxy resin was used.

### [Measurement of Modulus of Elasticity]

Tensile modulus of elasticity was measured with reference to Japanese Industrial Standards JIS 7127 and JIS K7161. As a measurement apparatus, EZ Graph manufactured by SHIMADZU CORPORATION was used. The distance between grippers for the samples was 50 mm. Each of the samples was processed into a 10-mm-wide strip form.

Bending modulus of elasticity was measured with reference to Japanese Industrial Standards JIS 7171. Although the standards set the sample thickness to be 1 mm or greater, samples thinner than this were also measured by a similar method. Each of the samples was processed into a 25-mm-wide strip form. The distance between lower supports for the sample was set to 40 mm, and three-point bending tests were performed.

The tensile modulus of elasticity and bending modulus of elasticity were obtained from the inclination between two points, i.e., the stress at a strain of 0.05% and the stress at a strain of 0.25%, on the stress-strain curve measured by the above-described way.

### <Results>

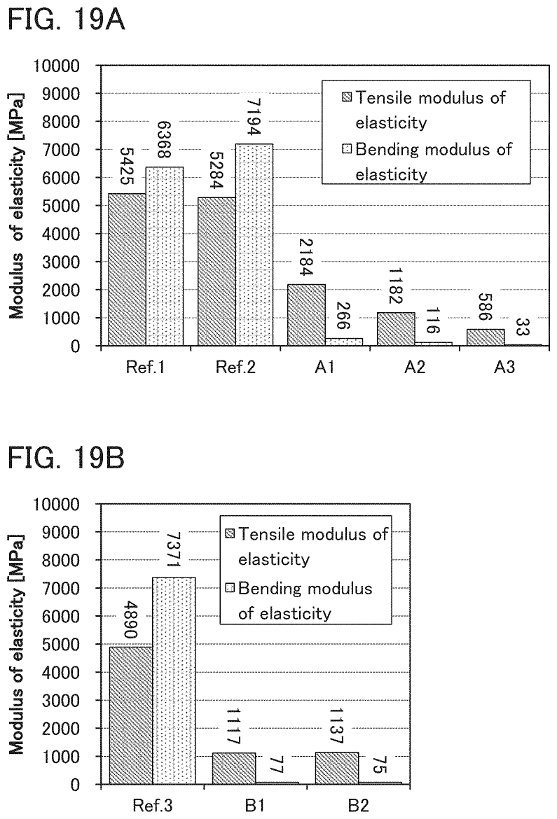

FIG. 19A shows the results of measuring the tensile modulus of elasticity and the bending modulus of elasticity of each sample.

As far as the comparative sample Ref 1 is concerned, first, the bending modulus of elasticity tends to be higher than the tensile modulus of elasticity. As to the comparative sample Ref 2, its tensile modulus of elasticity was lower, as compared with the comparative sample Ref 1, whereas its bending modulus of elasticity was higher. This indicates that attaching two films to each other with an adhesive decreases bendability.

Next, as far as the sample A1, the sample A2, and the sample A3 are concerned, the bending modulus of elasticity was lower than the tensile modulus of elasticity, in contrast to the comparative sample Ref 1 and the comparative sample Ref 2. This indicates that samples with a viscoelastic sheet can be bent with small force.

In addition, it was found from FIG. 19A that an increase in the thickness of the viscoelastic sheet made the bending modulus of elasticity lower.

Here, values that were obtained when the bending modulus of elasticity was divided by the tensile modulus of elasticity (i.e., the ratio of the bending modulus of elasticity to the tensile modulus of elasticity being 1) for the sample A1, the sample A2, and the sample A3 were as small as 0.12, 0.10, and 0.06, respectively, in contrast to those for the comparative sample Ref 1 and the comparative sample Ref 2 being 1.17 and 1.36, respectively, and exceeding 1.

### [Evaluation 2]

Then, samples with different stacked-layer structures from those described above were fabricated and similar evaluation was performed.

### [Samples]

Table 2 shows the stacked-layer structures of three samples that were fabricated and the thickness of each layer.

TABLE 2

| Sample | | |
|---|---|---|
| name | Stacked-layer structure | Thickness |
| Ref. 3 | PEN/epoxy resin/PEN/ | 100 μm/10 μm/100 μm/ |
| | epoxy resin/PEN | 10 μm/100 μm |
| B1 | PEN/viscoelastic sheet/PEN/ | 100 μm/300 μm/100 μm/ |
| | viscoelastic sheet/PEN | 300 μm/100 μm |
| B2 | PEN/viscoelastic sheet/PEN/ | 100 μm/300 μm/100 μm/ |
| | OCA/urethane | 50 μm/220 μm |

A sample B1 has a configuration where three PEN films are attached to each other with two viscoelastic sheets. A sample B2 has a configuration where a urethane sheet is further attached to the above sample A2 with an OCA (Optical Clear Adhesive) film. An acrylic-based resin material was used as the OCA film.

A comparative sample Ref 3 is composed of three PEN films attached to each other with an epoxy resin.

The measurement of tensile modulus of elasticity and bending modulus of elasticity was performed in a manner similar to the above.

### [Results]

FIG. 19B shows the results of measuring the tensile modulus of elasticity and the bending modulus of elasticity of each sample.

The bending modulus of elasticity tends to be higher than the tensile modulus of elasticity for the comparative sample Ref 3, similarly to the comparative sample Ref 2 above. In addition, the value of bending modulus of elasticity of the comparative sample Ref 3 was found to be higher than that of the comparative sample Ref 2.

As far as the sample B1 is concerned, its bending modulus of elasticity was lower than that of the sample A1 or the sample A2, even though the thickness of the sample B1 is considerably thick being approximately 0.9 mm.

The bending modulus of elasticity of the sample B2 was lower than the tensile modulus of elasticity by one order of magnitude or more, similarly to the sample A1 and the like. These results demonstrated that even use of a viscoelastic sheet in a portion of the stacked-layer structure alone was effective.

### [Observation of Shapes of Samples]

The results of observing the end portion of the sample A1 while changing the shape of the sample A1 will be described below.

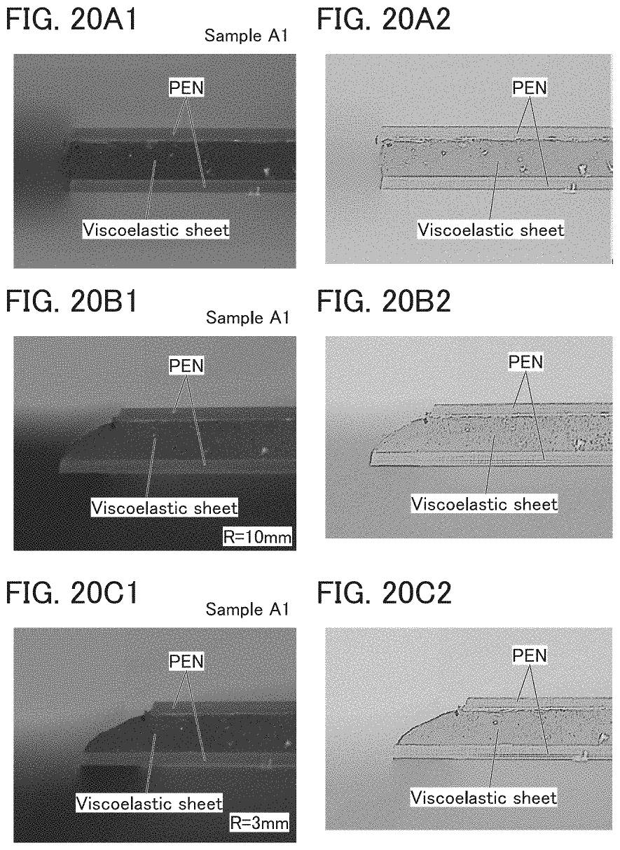

FIG. 20A1 is a micrograph of an end portion of the sample A1 which is in a flat state. FIG. 20A2 is a photograph in which image processing to emphasize the contours was performed on FIG. 20A1. As shown in FIG. 20A1 and FIG. 20A2, end portions of the pair of PEN films and an end portion of the viscoelastic sheet substantially align, when the sample A1 is flat.

FIG. 20B1 and FIG. 20B2 are micrographs of the sample A1 being bent with a diameter of 10 mm at a 180-degree angle. It can be seen from FIG. 20B1 and FIG. 20B2 that the lower PEN film protrudes to the outer side than the upper PEN film and that the end face of the viscoelastic sheet is changed in shape to be stretched. It can also been seen that the end face of the viscoelastic sheet is tilted to the end faces of the pair of PEN films and has a shape of a shallow arc.

FIG. 20C1 and FIG. 20C2 are micrographs of the sample A1 being bent with a diameter of 3 mm at a 180-degree angle. It shows almost the same shape as that of when bent with a diameter of 10 mm. In this way, it was found that the shape of the end portion of the sample A1 hardly changes regardless of the curvature.

### REFERENCE NUMERALS

10, 10A, 10R: display panel: 11, 12, 13: film: 21, 21a, 21b: bonding layer: 21R: adhesive: 26, 26a, 26b: FPC: 27, 27a, 27b: connector: 31, 31a, 31b: support: 32: bonding layer: 33, 34a, 34b, 34c, 34d, 34e, 34f, 34g, 34h, 34j, 34k: support: 35, 35a, 35b, 36: joint

1. A display device comprising a display panel with a display element,
wherein the display panel comprises a first film, a second film, and a first bonding layer,
wherein the first bonding layer is between the first film and the second film and capable of attaching the first film and the second film to each other,
wherein the display element is supported by the first film, and
wherein the display panel has a bending modulus of elasticity being higher than or equal to 0.01 times a tensile modulus of elasticity and lower than one times the tensile modulus of elasticity.

2. A display device comprising a display panel with a display element,
wherein the display panel comprises a first film, a second film, and a first bonding layer,
wherein the first bonding layer is between the first film and the second film and capable of attaching the first film and the second film to each other,
wherein the display element is supported by the first film,
wherein the display panel has a bending modulus of elasticity being higher than or equal to 0.01 times a tensile modulus of elasticity and lower than one times the tensile modulus of elasticity, and
wherein the first bonding layer has viscoelasticity and is higher in stretchability than the first film and the second film.

3. A display device comprising a display panel with a display element,
wherein the display panel comprises a first film, a second film, and a first bonding layer,
wherein the first bonding layer is between the first film and the second film and capable of attaching the first film and the second film to each other,
wherein the display element is supported by the first film,
wherein the display panel has a bending modulus of elasticity being higher than or equal to 0.01 times a tensile modulus of elasticity and lower than one times the tensile modulus of elasticity, and
wherein the display panel is changed in shape, when a portion of the display panel is bent, such that an end face of the first film and an end face of the second film relatively move away from each other.

4. The display device according to claim 1,
wherein the display panel has a bending modulus of elasticity being higher than or equal to 0.01 times the tensile modulus of elasticity and lower than or equal to 0.2 times the tensile modulus of elasticity.

5. The display device according to claim 1,
wherein the second film serves as a touch sensor or a circularly polarizing plate.

6. The display device according to claim 1,
wherein the first film comprises at least one of an epoxy resin, an aramid resin, an acrylic resin, an imide resin, an amide resin, an amide-imide resin, and glass.

7. The display device according to claim 1,
wherein the second film comprises at least one of a urethane resin, an acrylic resin, a silicone resin, a fluorine resin, an olefin resin, a vinyl resin, a styrene resin, an amide resin, an ester resin, and an epoxy resin.

8. The display device according to claim 1,
wherein the first bonding layer comprises a rubber-like or gel-like material comprising silicone, an acrylic resin, or a urethane resin.

9. The display device according to claim 1, further comprising:
a second bonding layer and a third film,
wherein the second bonding layer overlaps with the first bonding layer with the second film therebetween and is capable of attaching the second film and the third film to each other,
wherein the second bonding layer has viscoelasticity and is higher in stretchability than the first film and the second film, and
wherein the third film comprises at least one of a urethane resin, an acrylic resin, a silicone resin, a fluorine resin, an olefin resin, a vinyl resin, a styrene resin, an amide resin, an ester resin, and an epoxy resin.

10. An electronic device comprising the display device according to claim 1, and a protective cover,
wherein the protective cover comprises a first portion with a flat surface and a second portion with a curved surface adjacent to the first portion, and covers a display surface of the display panel, and
wherein the display panel is held by the protective cover along the first portion and the second portion.

11. An electronic device comprising the display device according to claim 1, a first support, a second support, and a joint,
wherein the first support and the second support are joined to each other with the joint,
wherein the display panel comprises a first portion supported by the first support, a second portion supported by the second support, and a third portion between the first portion and the second portion, and
wherein the joint is configured to allow the third portion of the display panel to be bent such that a display surface is convex or concave, thereby enabling the first support and the second support to overlap with each other.

12. An electronic device comprising the display device according to claim 1, a first support, a second support, a third support, a first joint, and a second joint,
wherein the first support and the second support are joined to each other with the first joint,
wherein the second support and the third support are joined to each other with the second joint,
wherein the display panel comprises a first portion supported by the first support, a second portion supported by the second support, a third portion supported by the third support, a fourth portion between the first portion and the second portion, and a fifth portion between the second portion and the third portion,
wherein the first joint is configured to allow the fourth portion of the display panel to be bent convexly, thereby enabling the first support and the second support to overlap with each other, and
wherein the second joint is configured to allow the fifth portion of the display panel to be bent concavely, thereby enabling the second support and the third support to overlap with each other.

13. The display device according to claim 2,
wherein the display panel has a bending modulus of elasticity being higher than or equal to 0.01 times the tensile modulus of elasticity and lower than or equal to 0.2 times the tensile modulus of elasticity.

14. The display device according to claim 2,
wherein the second film serves as a touch sensor or a circularly polarizing plate.

15. The display device according to claim 2,
wherein the first film comprises at least one of an epoxy resin, an aramid resin, an acrylic resin, an imide resin, an amide resin, an amide-imide resin, and glass.

16. The display device according to claim 2,
wherein the second film comprises at least one of a urethane resin, an acrylic resin, a silicone resin, a fluorine resin, an olefin resin, a vinyl resin, a styrene resin, an amide resin, an ester resin, and an epoxy resin.

17. The display device according to claim 2,
wherein the first bonding layer comprises a rubber-like or gel-like material comprising silicone, an acrylic resin, or a urethane resin.
